(19) United States
(12) Patent Application Publication
(10) Pub. No.: US 2024/0120246 A1
(43) Pub. Date: Apr. 11, 2024

(54) CORROSION REDUCTION AT LIQUID METAL/METAL INTERFACES BY SELECTIVE INTRINSIC ALLOYING

(71) Applicant: Meta Platforms Technologies, LLC, Menlo Park, CA (US)

(72) Inventors: Omar Awartani, Redmond, WA (US); Zhen Zheng, Bellevue, WA (US); Marcos Antonio Santana Andrade, JR., Seattle, WA (US); Kristopher Erickson, Sammamish, WA (US); Alejandra Alvarez Albarran, Bellevue, WA (US); Allison Tuuri, Seattle, WA (US)

(21) Appl. No.: 18/479,780

(22) Filed: Oct. 2, 2023

Related U.S. Application Data
(60) Provisional application No. 63/412,335, filed on Sep. 30, 2022.

(51) Int. Cl. H01L 23/29; H01B 1/22; H01L 21/48; H01L 23/498

(52) U.S. Cl. CPC H01L 23/298; H01B 1/22; H01L 21/4857; H01L 21/486; H01L 23/49822; H01L 23/4985; H01L 23/49872

(57) ABSTRACT

An electronic device includes a substrate and a circuit having a plurality of electrically-conductive components disposed on the substrate. The plurality of electrically-conductive components includes first, second and third electrically-conductive components. The third electrically-conductive component has a first end portion forming a first interface with the first electrically-conductive component and a second end portion forming a second interface with the second electrically conductive component. The first electrically-conductive component is made of a first material including a first metal. The second electrically-conductive component is made of a second material including the first metal. The third electrically-conductive component is made of a third material including a gallium-based alloy and a metallic filler. The metallic filler reduces a reactivity of the third electrically-conductive component with the first metal at the first and second interfaces, and thus minimizes deterioration of the first electrically-conductive component and the second electrically-conductive component over time.

### CROSS-REFERENCE TO RELATED APPLICATION

The present application claims priority to U.S. Provisional Patent Application No. 63/412,335, entitled “Corrosion Reduction At Liquid Metal/Metal Interfaces By Selective Intrinsic Alloying,” filed Sep. 30, 2022, which is hereby incorporated by reference in its entirety for all purposes.

### FIELD OF THE PRESENT DISCLOSURE

The present application relates to improved integrated circuits with selective intrinsic alloying to reduce corrosion at liquid metal/metal interfaces, and methods of making the same.

### BACKGROUND

Gallium-based (Ga-based) liquid metal alloys and their composite inks are very promising for stretchable electronics due to their high electrical conductivity and extreme deformability. However, Ga-based alloys react with other metallic contacts, such as pads or electrodes, either dissolving them or corroding them. As a result, it often causes embrittlement, and open circuit in extreme situations, at the interfaces/interconnects between liquid metal and other metallic components. This creates challenges in the use of these inks for integrated circuits due to the risk of contact degradation and instability over time.

Accordingly, there is a need in the art for improved integrated circuits with reduced corrosion at liquid metal/metal interfaces.

### SUMMARY

One aspect of the present disclosure provides an electronic device, including a substrate and a circuit having a plurality of electrically-conductive components disposed on the substrate. The plurality of electrically-conductive components includes first, second and third electrically-conductive components. The first electrically-conductive component is disposed at a first portion of the substrate and is made of a first material including a first metal. The second electrically-conductive component is disposed at a second portion of the substrate and is made of a second material including the first metal. The third electrically-conductive component includes a first end portion and a second end portion, with the first end portion forming a first interface with the first electrically-conductive component and the second end portion forming a second interface with the second electrically-conductive component. The third electrically-conductive component is made of a third material including a gallium-based (Ga-based) alloy and a metallic filler, and forms an electrical conduit between the first interface and the second interface. The metallic filler reduces a reactivity of the third electrically-conductive component with the first metal at the first and second interfaces so that each of the first and second interfaces is free of deterioration in conductivity for a period of time, wherein the period of time is at least 1000 hours.

In some embodiments, the substrate is a deformable substrate.

In some embodiments, the substrate includes one or more layers, with the first, second and third electrically-conductive components disposed in a common layer of the substrate. Alternatively, in some embodiments, the substrate includes a plurality of layers, with the first electrically-conductive component disposed in a first layer of the substrate and the second electrically-conductive component disposed in a second different layer of the substrate.

In some embodiments, the first electrically-conductive component is a first metallic pad or a first electrode, and the second electrically-conductive component is a second metallic pad or a second electrode.

In some embodiments, the third electrically-conductive component is a single trace or a plurality of traces. Alternatively, in some embodiments, the third electrically-conductive component is a via between the first layer and the second different layer.

In some embodiments, the first metal is silver, copper, gold, titanium, nitinol, tungsten, or any combination thereof.

In some embodiments, the Ga-based alloy is a Ga-based liquid metal alloy. In some embodiments, the Ga-based liquid metal alloy includes at least one of gallium indium alloy, gallium tin alloy, gallium indium tin alloy, or gallium indium tin zinc alloy.

In some embodiments, the metallic filler is in the form of microflakes, nanoflakes, microparticles, nanoparticles, nanowires, nanotubes, or a combination thereof. In some embodiments, an amount of the metallic filler in the third material is from about 10% to about 30% by weight, from about 10% to about 40% by weight, or from about 10% to about 50% by weight of the Ga-based alloy.

In some embodiments, the third material further includes a polymeric binder, a solvent, or both.

In some embodiments, the metallic filler includes the first metal. In an embodiment, the first metal is silver, titanium, nitinol, or tungsten, the Ga-based alloy is a Ga-based liquid metal alloy, and the metallic filler includes silver, titanium, nitinol, or tungsten in the form of microflakes, nanoflakes, microparticles, nanoparticles, nanowires, nanotubes, or a combination thereof and mixed with the Ga-based liquid metal alloy.

In some embodiments, the metallic filler includes a second metal different than the first metal. In an embodiment, the first metal is silver, the Ga-based alloy is a Ga-based liquid metal alloy, and the metallic filler includes copper or gold in the form of microflakes, nanoflakes, microparticles, nanoparticles, nanowires, nanotubes, or a combination thereof and mixed with the Ga-based liquid metal alloy.

In some embodiments, the metallic filler reduces the reactivity of the Ga-based alloy with the first metal that would otherwise cause corrosion, embrittlement, degradation, or open circuit of the first electrically-conductive component at the first interface and corrosion, embrittlement, degradation, or open circuit of the second electrically-conductive component at second interface.

Another aspect of the present disclosure provides a method for fabricating an electronic device that includes at least one a first electrically-conductive component, at least one second electrically-conductive component, and at least one third electrically-conductive component. The method includes forming a first electrically-conductive component at a first portion of a substrate and forming a second electrically-conductive component at a second portion of the substrate. The first electrically-conductive component is made of a first material including a first metal, and the second electrically-conductive component is made of a second material including the first metal.

The method also includes connecting the second electrically-conductive component with the first electrically-conductive component by a third electrically-conductive component. The third electrically-conductive component is made of a third material including a Ga-based alloy and a metallic filler. The metallic filler reduces a reactivity of the third electrically-conductive component with the first metal at the first and second interfaces so that each of the first and second interfaces is free of deterioration in conductivity for a period of time, wherein the period of time is at least 1000 hours.

In some embodiments, third electrically-conductive component is printed on the substrate between the first and second electrically-conductive components.

In some embodiments, the third electrically-conductive component is a line or via.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a block diagram schematically illustrating an electronic device in accordance with some embodiments of the present disclosure.

FIGS. 2A, 2B, 2C and 2D schematically illustrate exemplary interfaces in accordance with some embodiments of the present disclosure.

FIG. 3 schematically illustrates an exemplary circuit in accordance with some embodiments of the present disclosure.

FIG. 4 is a flowchart illustrating a method for manufacturing an electrical circuit, in which optional embodiments are indicated by dashed boxes, in accordance with some embodiments of the present disclosure.

FIGS. 5A, 5B, 5C and 5D collectively presents a flowchart illustrating a method for manufacturing an exemplary circuit of an electronic device in accordance with some embodiments of the present disclosure.

FIGS. 6A, 6B, 6C, 6D and 6E collectively presents a flowchart illustrating a method for manufacturing another exemplary circuit of an electronic device in accordance with some embodiments of the present disclosure.

FIG. 7 illustrates exemplary logic functions that can be implemented into an exemplary circuit of an electronic device in accordance with some embodiments of the present disclosure.

FIG. 8 shows interactions between a liquid metal and different interconnect materials after 500 hours of thermal cycles from −30° C. to 75° C. in accordance with some embodiments of the present disclosure.

FIG. 9 is a plot showing measured resistances of testing samples with different interconnect materials at different times during a thermal cycling test in accordance with some embodiments of the present disclosure.

FIG. 10 shows images of testing samples with different interconnect materials after 150 hours of thermal cycles from −30° C. to 75° C. in accordance with some embodiments of the present disclosure.

FIG. 11 shows images of testing samples with different interconnect materials after 300 hours of thermal cycles from −30° C. to 75° C. in accordance with some embodiments of the present disclosure.

FIG. 12 shows images of testing samples with different interconnect materials after 500 hours of thermal cycles from −30° C. to 75° C. in accordance with some embodiments of the present disclosure.

FIG. 13 shows resistance graphs of an EGaIn channel with a copper wire electrical terminal before thermal cycling test, after 150 hours of thermal cycles, after 300 hours of thermal cycles and after 500 hours of thermal cycles in accordance with some embodiments of the present disclosure.

FIG. 14, FIG. 15, FIG. 16 and FIG. 17 show chemical reactivity of EGaIn with copper after 500 hours of thermal cycles in accordance with some embodiments of the present disclosure.

FIG. 18 shows resistance graphs of an EGaIn channel with a nitinol wire electrical terminal before thermal cycling test, after 150 hours of thermal cycles, after 300 hours of thermal cycles and after 500 hours of thermal cycles in accordance with some embodiments of the present disclosure.

FIG. 19 and FIG. 20 show chemical reactivity of EGaIn with nitinol after 500 hours of thermal cycles in accordance with some embodiments of the present disclosure.

FIG. 21 shows resistance graphs of an EGaIn channel with a titanium wire electrical terminal before thermal cycling test, after 150 hours of thermal cycles, after 300 hours of thermal cycles and after 500 hours of thermal cycles in accordance with some embodiments of the present disclosure.

FIG. 22 shows chemical reactivity of EGaIn with titanium after 500 hours of thermal cycles in accordance with some embodiments of the present disclosure.

FIG. 23 shows resistance graphs of an EGaIn channel with a tungsten wire electrical terminal before thermal cycling test, after 150 hours of thermal cycles, after 300 hours of thermal cycles and after 500 hours of thermal cycles in accordance with some embodiments of the present disclosure.

FIG. 24 and FIG. 25 show chemical reactivity of EGaIn with tungsten after 500 hours of thermal cycles in accordance with some embodiments of the present disclosure.

### DETAILED DESCRIPTION OF THE INVENTION

The present disclosure is directed to the use of selective intrinsic alloying to reduce corrosion at liquid metal/metal interfaces and thus improve the integrity and stability of circuits, such as integrated circuits. In various embodiments, the present disclosure provides an electronic device that includes a circuit having one or more components made of a mixture of a Ga-based alloy and a metallic filler. The metallic filler reduces the reactivity of the Ga-based alloy with desired metallic contact(s), and consequently reduces the risk of potential contact degradation and instability over time.

Before the invention is described in greater detail, it is to be understood that the invention is not limited to particular embodiments described herein as such embodiments may vary. It is also to be understood that the terminology used herein is for the purpose of describing particular embodiments only, and the terminology is not intended to be limiting. The scope of the invention will be limited only by the appended claims. Unless defined otherwise, all technical and scientific terms used herein have the same meaning as commonly understood by one of ordinary skill in the art to which this invention belongs. Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

The term “about” or “approximately” is used herein to provide literal support for the exact number that it precedes, as well as a number that is near to or approximately the number that the term precedes. In determining whether a number is near to or approximately a specifically recited number, the near or approximating unrecited number may be a number, which, in the context in which it is presented, provides the substantial equivalent of the specifically recited number. It should be appreciated that all numerical values and ranges disclosed herein are approximate values and ranges, whether “about” is used in conjunction therewith. It should also be appreciated that the term “about,” as used herein, in conjunction with a numeral refers to a value that may be ±0.01% (inclusive), ±0.1% (inclusive), ±0.5% (inclusive), ±1% (inclusive) of that numeral, ±2% (inclusive) of that numeral, ±3% (inclusive) of that numeral, ±5% (inclusive) of that numeral, ±10% (inclusive) of that numeral, or ±15% (inclusive) of that numeral. It should further be appreciated that when a numerical range is disclosed herein, any numerical value falling within the range is also specifically disclosed.

Furthermore, when a reference number is given an “i^{th}” denotation, the reference number refers to a generic component, set, or embodiment. For instance, a layer “layer i” refers to the i^{th} layer in a plurality of layers.

All publications, patents, and patent applications cited in this specification are incorporated herein by reference to the same extent as if each individual publication, patent, or patent application were specifically and individually indicated to be incorporated by reference. Furthermore, each cited publication, patent, or patent application is incorporated herein by reference to disclose and describe the subject matter in connection with which the publications are cited. The citation of any publication is for its disclosure prior to the filing date and should not be construed as an admission that the invention described herein is not entitled to antedate such publication by virtue of prior invention. Further, the dates of publication provided might be different from the actual publication dates, which may need to be independently confirmed.

It is noted that the claims may be drafted to exclude any optional element. As such, this statement is intended to serve as antecedent basis for use of such exclusive terminology as “solely,” “only,” and the like in connection with the recitation of claim elements, or use of a “negative” limitation. As will be apparent to those of skill in the art upon reading this disclosure, each of the individual embodiments described and illustrated herein has discrete components and features which may be readily separated from or combined with the features of any of the other several embodiments without departing from the scope or spirit of the invention. Any recited method may be carried out in the order of events recited or in any other order that is logically possible. Although any methods and materials similar or equivalent to those described herein may also be used in the practice or testing of the invention, representative illustrative methods and materials are now described.

Below are examples of specific embodiments of the present disclosure. The examples are offered for illustrative purposes only, and are not intended to limit the scope of the present invention in any way.

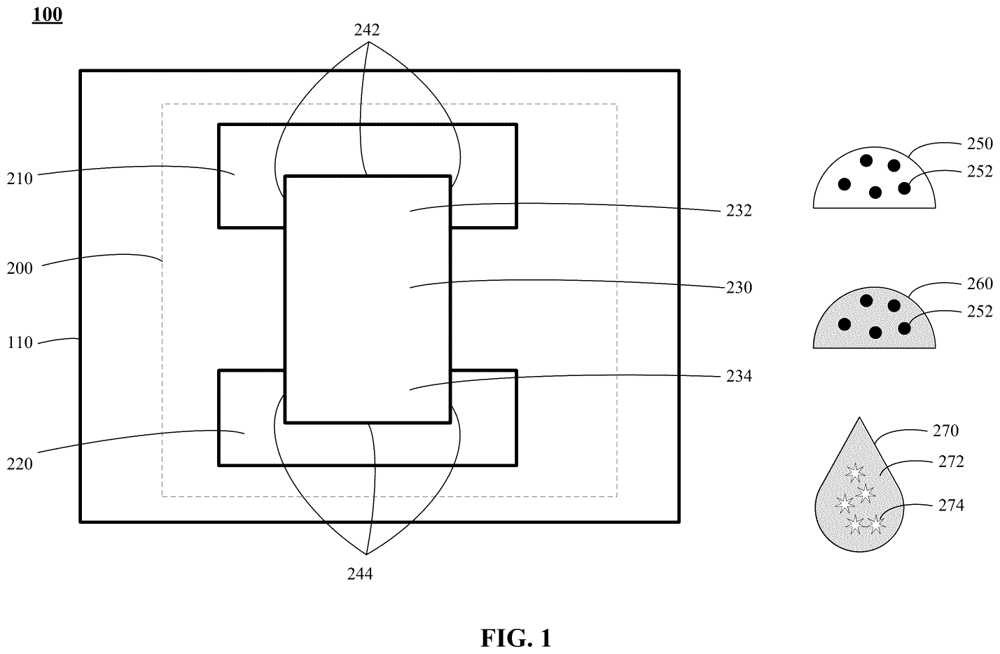

FIG. 1 is a block diagram schematically illustrating an electronic device 100 in accordance with some embodiments of the present disclosure. The electronic device 100 includes a substrate 110 and a first circuit 200. The first circuit 200 is formed, applied, secured, or otherwise affixed to the substrate 110.

In some embodiments, the electronic device 100 consists of only the first circuit 200. Alternatively, in some embodiments, the electronic device 100 includes the first circuit 200, and at least one additional circuit (e.g., one, two, three, four, five, or more than five additional circuits). For instance, in an embodiment, the electronic device includes an antenna circuit configured to receive or transmit wireless signals in communications with an external device and the first circuit is in communication with the antenna circuit. In some embodiments, the first circuit includes an antenna circuit configured to receive or transmit wireless signals in communications with an external device. In some embodiments, the electronic device includes one, two, three, four, five, or more than five semiconductor chips, which, in combination with the first circuit can perform some specific functions. For instance, in an embodiment, the electronic device includes one or more semiconductor chips, which in combination with the first circuit is able to wirelessly communicate with an external device based on near field communication (NFC), Wi-Fi, Bluetooth, RFID wireless communication standard, or the like.

In some embodiments, the substrate 110 is a deformable substrate. As used herein, the term “deformable substrate” refers to a substrate or a portion of it (e.g., a layer) capable of altering its shape subject to pressure or stress. For instance, in some embodiments, the substrate or at least a portion of it is flexible, bendable, stretchable, inflatable, or the like. In some embodiments, the deformable substrate or at least a portion of it (e.g., a layer) is made with a material having a Young's Modulus lower than about 0.5, lower than about 0.4 Gpa, lower than about 0.3 Gpa, or lower than about 0.2 Gpa. Such a material allows the substrate or a portion of it to deform (e.g., bend, stretch or the like) under pressure or strain. In some embodiments, the deformable substrate or at least a portion of it is made of a material having Young's Modulus lower than about 0.1 Gpa to provide enhanced flexibility and tackability. Examples of materials with low Young's Modulus include, but are not limited to elastomeric materials, viscoelastic polymeric materials, synthetic resins having low sliding performance, high corrosion resistance and high strength, such as silicone, medical grade polyurethane, polyethylene terephthalate (PET), polyimide (PI), polyphenylene sulfide (PPS) or fluorine-containing resin.

In some embodiments, the deformable substrate includes a layer or a portion made of a relatively rigid material. For instance, in some embodiments, the deformable substrate includes a layer or a portion made of a material having Young's Modulus higher than about 0.5 Gpa, higher than about 1.0 Gpa, higher than about 2.0 Gpa, higher than about 3.0 Gpa, higher than 4.0 Gpa, or higher than about 5.0 Gpa. Examples of materials with relatively higher Young's Modulus include, but are not limited to, polyethylene, PEEK, polyester, aramid, composite, glass epoxy, and polyethylene naphalate.

In some embodiments, the deformable substrate includes a supporting material upon or within an object is fabricated or attached to or on. In some embodiments, the deformable substrate or a portion of the deformable substrate is processed (e.g., patterned) during manufacture of the object. In some embodiments, the deformable substrate remains substantially unchanged when the object is formed upon or within the deformable substrate. In some embodiments, the deformable substrate includes a planar surface, a substantially planar surface, a curved surface, a round surface (e.g., an edge having a radius of curvature greater than zero), one or more sharp edges, or any combination thereof.

In some embodiments, the deformable substrate is a monolayer substrate consisting of a single layer. In some embodiments, the deformable substrate includes two, three, four, five, or more than five layers. In some embodiments, the deformable substrate includes one or more layers that are removable, e.g., functioning as a sacrificial layer that can be at least partially removed when desired or needed.

The first circuit 200 includes a plurality of circuit components. For instance, in some embodiments, the first circuit includes at least 3 circuit components, at least 5 circuit components, at least 10 circuit components, at least 50 circuit components, at least 100 circuit components, at least 500 circuit components, at least 1,000 circuit components, at least 5,000 circuit components, at least 10,000 circuit components, at least 25,000 circuit components, at least 40,000 circuit components, at least 100,000 circuit components, at least 250,000 circuit components, at least 500,000 circuit components, at least 1 million circuit components, at least 5 million circuit components, or at least 10 million circuit components.

The plurality of circuit components of the first circuit 200 includes at least 3 electrically-conductive components. As used herein, the term “electrically-conductive component” refers to a component made of a material having a resistivity of less than about 1000×10⁻⁸ ohm metre (Om), less than about 800×10⁻⁸ Ωm, less than about 600×10⁻⁸ Ωm, less than about 400×10⁻⁸ Ωm, less than about 200×10⁻⁸ Ωm, less than about 100×10⁻⁸ Ωm, less than about 80×10⁻⁸ Ωm, less than about 60×10⁻⁸ Ωm, less than about 40×10⁻⁸ Ωm, less than about 20×10⁻⁸ Ωm, less than about 10×10⁻⁸ Ωm, less than about 8×10⁻⁸ Ωm, less than about 6×10⁻⁸ Ωm, or less than about 4×10⁻⁸ Ωm. Non-limiting examples of electrically-conductive components include, but are not limited to, metal pads, electrodes, metal wires, lines, vias or the like.

In some embodiments, additionally or optionally, the plurality of circuit components of the first circuit 200 includes leads, terminals, capacitors, inductors, resistors, diodes, transistors, amplifiers, or any combination thereof.

By way of example, FIG. 1 illustrates the first circuit 200 including a first electrically-conductive component 210, a second electrically-conductive component 220 and a third electrically-conductive component 230. The first electrically-conductive component 210 is made of a first material 250 including a first metal 252, and the second electrically-conductive component 220 is made of a second material 260 including the first metal 252. Non-limiting examples of the first metal 252 include, but are not limited to, aluminum, titanium, cobalt, nickel, tin, lead, cadmium, zinc, indium, copper, silver, gold, platinum, nitinol, or tungsten or any combination thereof. For instance, in an embodiment, the first metal 252 is silver. In another embodiments, the first metal 252 is copper. In a further embodiment, the first metal 252 is a mixture of copper, silver and/or gold. In a still further embodiment, the first metal 252 is a mixture of tin, lead, cadmium, zinc, and/or indium. In some embodiments, the first metal 252 includes a metal alloy, such as nitinols (nickel-titanium alloys) or the like.

While both the first and second materials contain the first metal 252, it should be noted that the first and second materials can be the same as each other or different from each other. For instance, as a non-limiting example, in some embodiments, each of the first and second materials consists of essentially only the first metal 252 (e.g., copper or silver). As another non-limiting example, in some embodiments, one of the first and second materials consists of essentially only the first metal 252 (e.g., copper) and the other of the first and second materials is a mixture of the first metal 252 (e.g., copper) with one or more additional components other than the first metal 252 (e.g., tin, silver, gold, indium, or the like). As a further non-limiting example, in some embodiments, one of the first and second materials is a mixture of the first metal 252 (e.g., copper) and a second metal (e.g., silver) and the other of the first and second materials is a mixture of the first metal 252 (e.g., copper) and a different third metal (e.g., tin, gold, indium).

The first electrically-conductive component 210 and the second electrically-conductive component 220 can independently be any electrically-conductive component in the first circuit 200. Non-limiting examples of an electrically conductive component include, but are not limited to, a metallic pad, an electrode, a via, or a line (e.g., a conducting track or trace). For instance, in an embodiment, at least one of the first and second electrically-conductive components is a metallic pad or an electrode of the first circuit. In another embodiment, at least one of the first and second electrically-conductive components is a line of the first circuit. In a further embodiment, at least one of the first and second electrically-conductive components is a via of the first circuit.

In some embodiments, the first electrically-conductive component 210 and the second electrically-conductive component 220 form part of an active-matrix array. For instance, in some embodiments, the first electrically-conductive component 210 or the second electrically-conductive component 220 is a transistor, an electrode, or a capacitor disposed on the deformable substrate 320, and the other of the first electrically-conductive component 210 or the second electrically-conductive component 220 is different than the transistor, the electrode, or the capacitor of the first electrically-conductive component 210 or the second electrically-conductive component 220.

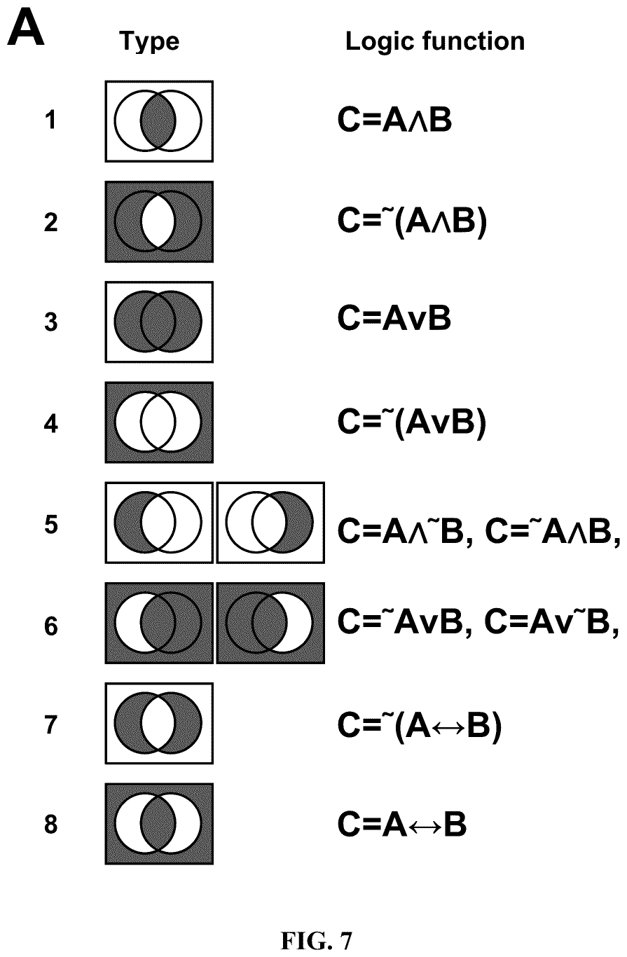

In some embodiments, the first electrically-conductive component 210 and the second electrically-conductive component 220 are part of a transistor switch. For instance, in some embodiments, the transistor switch is configured to control an electronical communication through the circuit 200 using a logic function, such as an OR logic function based on either a cutoff or saturation of the electronical communication. In some embodiments, two or more transistor switches are arranged (e.g., in series and/or parallel) in order to implement a logic function, such as one or more logic functions of FIG. 7.

As used herein, the term “line” refers to a conducting track or trace having a thickness less than a thickness threshold, a width less than a width threshold, or both. In some embodiments, the thickness of a line is less than about 500 μm, less than about 450 μm, less than about 400 μm, less than about 350 μm, less than about 300 μm, less than about 250 μm, less than about 200 μm, less than about 150 μm, or less than about 100 μm. In some embodiments, the width of a line is less than about 1000 μm, less than about 900 μm, less than about 800 μm, less than about 700 μm, less than about 600 μm, less than about 500 μm, less than about 400 μm, less than about 300 μm, or less than about 200 μm.

As used herein, the term “via” refers to a vertical interconnect access having a nominal (e.g., mean or average) diameter less than a diameter or width threshold. A cross section of a via can be, but does not necessarily have to be, a circle. For instance, a cross section of a via can be any regular closed form shape such as a circle or a polygon of the form N-gon, where here N is a positive integer of 3 or greater, or an irregular closed form shape, or the like.

In some embodiments, the nominal diameter or a width of a cross-section of a via is between 10 μm and 500 μm. For instance, in some embodiments, the nominal diameter or a width of a cross-section of the via is between 5 μm and 1000 μm (e.g., 0.1 centimeters (cm)), between 5 μm and 975 μm, between 5 μm and 950 μm, between 5 μm and 925 μm, between 5 μm and 900 μm, between 5 μm and 875 μm, between 5 μm and 850 μm, between 5 μm and 825 μm, between 5 μm and 800 μm, between 5 μm and 775 μm, between 5 μm and 750 μm, between 5 μm and 725 μm, between 5 μm and 700 μm, between 5 μm and 675 μm, between 5 μm and 650 μm, between 5 μm and 625 μm, between 5 μm and 600 μm, between 5 μm and 575 μm, between 5 μm and 550 μm, between 5 μm and 525 μm, between 5 μm and 500 μm, between 5 μm and 475 μm, between 5 μm and 450 μm, between 5 μm and 425 μm, between 5 μm and 400 μm, between 5 μm and 375 μm, between 5 μm and 350 μm, between 5 μm and 325 μm, between 5 μm and 300 μm, between 5 μm and 275 μm, between 5 μm and 250 μm, between 5 μm and 225 μm, between 5 μm and 200 μm, between 5 μm and 175 μm, between 5 μm and 150 μm, between 5 μm and 125 μm, between 5 μm and 100 μm, between 5 μm and 75 μm, between 5 μm and 50 μm, between 5 μm and 25 μm, between 5 μm and 10 μm, between 10 μm and 975 μm, between 10 μm and 950 μm, between 10 μm and 925 μm, between 10 μm and 900 μm, between 10 μm and 875 μm, between 10 μm and 850 μm, between 10 μm and 825 μm, between 10 μm and 800 μm, between 10 μm and 775 μm, between 10 μm and 750 μm, between 10 μm and 725 μm, between 10 μm and 700 μm, between 10 μm and 675 μm, between 10 μm and 650 μm, between 10 μm and 625 μm, between 10 μm and 600 μm, between 10 μm and 575 μm, between 10 μm and 550 μm, between 10 μm and 525 μm, between 10 μm and 500 μm, between 10 μm and 475 μm, between 10 μm and 450 μm, between 10 μm and 425 μm, between 10 μm and 400 μm, between 10 μm and 375 μm, between 10 μm and 350 μm, between 10 μm and 325 μm, between 10 μm and 300 μm, between 10 μm and 275 μm, between 10 μm and 250 μm, between 10 μm and 225 μm, between 10 μm and 200 μm, between 10 μm and 175 μm, between 10 μm and 150 μm, between 10 μm and 125 μm, between 10 μm and 100 μm, between 10 μm and 75 μm, between 10 μm and 50 μm, between 10 μm and 25 μm, between 30 μm and 975 μm, between 30 μm and 950 μm, between 30 μm and 925 μm, between 30 μm and 900 μm, between 30 μm and 875 μm, between 30 μm and 850 μm, between 30 μm and 825 μm, between 30 μm and 800 μm, between 30 μm and 775 μm, between 30 μm and 750 μm, between 30 μm and 725 μm, between 30 μm and 700 μm, between 30 μm and 675 μm, between 30 μm and 650 μm, between 30 μm and 625 μm, between 30 μm and 600 μm, between 30 μm and 575 μm, between 30 μm and 550 μm, between 30 μm and 525 μm, between 30 μm and 500 μm, between 30 μm and 475 μm, between 30 μm and 450 μm, between 30 μm and 425 μm, between 30 μm and 400 μm, between 30 μm and 375 μm, between 30 μm and 350 μm, between 30 μm and 325 μm, between 30 μm and 300 μm, between 30 μm and 275 μm, between 30 μm and 250 μm, between 30 μm and 225 μm, between 30 μm and 200 μm, between 30 μm and 175 μm, between 30 μm and 150 μm, between 30 μm and 125 μm, between 30 μm and 100 μm, between 30 μm and 75 μm, between 30 μm and 50 μm, between 50 μm and 975 μm, between 50 μm and 950 μm, between 50 μm and 925 μm, between 50 μm and 900 μm, between 50 μm and 875 μm, between 50 μm and 850 μm, between 50 μm and 825 μm, between 50 μm and 800 μm, between 50 μm and 775 μm, between 50 μm and 750 μm, between 50 μm and 725 μm, between 50 μm and 700 μm, between 50 μm and 675 μm, between 50 μm and 650 μm, between 50 μm and 625 μm, between 50 μm and 600 μm, between 50 μm and 575 μm, between 50 μm and 550 μm, between 50 μm and 525 μm, between 50 μm and 500 μm, between 50 μm and 475 μm, between 50 μm and 450 μm, between 50 μm and 425 μm, between 50 μm and 400 μm, between 50 μm and 375 μm, between 50 μm and 350 μm, between 50 μm and 325 μm, between 50 μm and 300 μm, between 50 μm and 275 μm, between 50 μm and 250 μm, between 50 μm and 225 μm, between 50 μm and 200 μm, between 50 μm and 175 μm, between 50 μm and 150 μm, between 50 μm and 125 μm, between 50 μm and 100 μm, between 50 μm and 75 μm, between 70 μm and 975 μm, between 70 μm and 950 μm, between 70 μm and 925 μm, between 70 μm and 900 μm, between 70 μm and 875 μm, between 70 μm and 850 μm, between 70 μm and 825 μm, between 70 μm and 800 μm, between 70 μm and 775 μm, between 70 μm and 750 μm, between 70 μm and 725 μm, between 70 μm and 700 μm, between 70 μm and 675 μm, between 70 μm and 650 μm, between 70 μm and 625 μm, between 70 μm and 600 μm, between 70 μm and 575 μm, between 70 μm and 550 μm, between 70 μm and 525 μm, between 70 μm and 500 μm, between 70 μm and 475 μm, between 70 μm and 450 μm, between 70 μm and 425 μm, between 70 μm and 400 μm, between 70 μm and 375 μm, between 70 μm and 350 μm, between 70 μm and 325 μm, between 70 μm and 300 μm, between 70 μm and 275 μm, between 70 μm and 250 μm, between 70 μm and 225 μm, between 70 μm and 200 μm, between 70 μm and 175 μm, between 70 μm and 150 μm, between 70 μm and 125 μm, between 70 μm and 100 μm, between 70 μm and 75 μm, between 90 μm and 975 μm, between 90 μm and 950 μm, between 90 μm and 925 μm, between 90 μm and 900 μm, between 90 μm and 875 μm, between 90 μm and 850 μm, between 90 μm and 825 μm, between 90 μm and 800 μm, between 90 μm and 775 μm, between 90 μm and 750 μm, between 90 μm and 725 μm, between 90 μm and 700 μm, between 90 μm and 675 μm, between 90 μm and 650 μm, between 90 μm and 625 μm, between 90 μm and 600 μm, between 90 μm and 575 μm, between 90 μm and 550 μm, between 90 μm and 525 μm, between 90 μm and 500 μm, between 90 μm and 475 μm, between 90 μm and 450 μm, between 90 μm and 425 μm, between 90 μm and 400 μm, between 90 μm and 375 μm, between 90 μm and 350 μm, between 90 μm and 325 μm, between 90 μm and 300 μm, between 90 μm and 275 μm, between 90 μm and 250 μm, between 90 μm and 225 μm, between 90 μm and 200 μm, between 90 μm and 175 μm, between 90 μm and 150 μm, between 90 μm and 125 μm, between 90 μm and 100 μm, between 110 μm and 975 μm, between 110 μm and 950 μm, between 110 μm and 925 μm, between 110 μm and 900 μm, between 110 μm and 875 μm, between 110 μm and 850 μm, between 110 μm and 825 μm, between 110 μm and 800 μm, between 110 μm and 775 μm, between 110 μm and 750 μm, between 110 μm and 725 μm, between 110 μm and 700 μm, between 110 μm and 675 μm, between 110 μm and 650 μm, between 110 μm and 625 μm, between 110 μm and 600 μm, between 110 μm and 575 μm, between 110 μm and 550 μm, between 110 μm and 525 μm, between 110 μm and 500 μm, between 110 μm and 475 μm, between 110 μm and 450 μm, between 110 μm and 425 μm, between 110 μm and 400 μm, between 110 μm and 375 μm, between 110 μm and 350 μm, between 110 μm and 325 μm, between 110 μm and 300 μm, between 110 μm and 275 μm, between 110 μm and 250 μm, between 110 μm and 225 μm, between 110 μm and 200 μm, between 110 μm and 175 μm, between 110 μm and 150 μm, between 110 μm and 125 μm, between 130 μm and 975 μm, between 130 μm and 950 μm, between 130 μm and 925 μm, between 130 μm and 900 μm, between 130 μm and 875 μm, between 130 μm and 850 μm, between 130 μm and 825 μm, between 130 μm and 800 μm, between 130 μm and 775 μm, between 130 μm and 750 μm, between 130 μm and 725 μm, between 130 μm and 700 μm, between 130 μm and 675 μm, between 130 μm and 650 μm, between 130 μm and 625 μm, between 130 μm and 600 μm, between 130 μm and 575 μm, between 130 μm and 550 μm, between 130 μm and 525 μm, between 130 μm and 500 μm, between 130 μm and 475 μm, between 130 μm and 450 μm, between 130 μm and 425 μm, between 130 μm and 400 μm, between 130 μm and 375 μm, between 130 μm and 350 μm, between 130 μm and 325 μm, between 130 μm and 300 μm, between 130 μm and 275 μm, between 130 μm and 250 μm, between 130 μm and 225 μm, between 130 μm and 200 μm, between 130 μm and 175 μm, between 130 μm and 150 μm, between 150 μm and 975 μm, between 150 μm and 950 μm, between 150 μm and 925 μm, between 150 μm and 900 μm, between 150 μm and 875 μm, between 150 μm and 850 μm, between 150 μm and 825 μm, between 150 μm and 800 μm, between 150 μm and 775 μm, between 150 μm and 750 μm, between 150 μm and 725 μm, between 150 μm and 700 μm, between 150 μm and 675 μm, between 150 μm and 650 μm, between 150 μm and 625 μm, between 150 μm and 600 μm, between 150 μm and 575 μm, between 150 μm and 550 μm, between 150 μm and 525 μm, between 150 μm and 500 μm, between 150 μm and 475 μm, between 150 μm and 450 μm, between 150 μm and 425 μm, between 150 μm and 400 μm, between 150 μm and 375 μm, between 150 μm and 350 μm, between 150 μm and 325 μm, between 150 μm and 300 μm, between 150 μm and 275 μm, between 150 μm and 250 μm, between 150 μm and 225 μm, between 150 μm and 200 μm, between 150 μm and 175 μm, between 170 μm and 975 μm, between 170 μm and 950 μm, between 170 μm and 925 μm, between 170 μm and 900 μm, between 170 μm and 875 μm, between 170 μm and 850 μm, between 170 μm and 825 μm, between 170 μm and 800 μm, between 170 μm and 775 μm, between 170 μm and 750 μm, between 170 μm and 725 μm, between 170 μm and 700 μm, between 170 μm and 675 μm, between 170 μm and 650 μm, between 170 μm and 625 μm, between 170 μm and 600 μm, between 170 μm and 575 μm, between 170 μm and 550 μm, between 170 μm and 525 μm, between 170 μm and 500 μm, between 170 μm and 475 μm, between 170 μm and 450 μm, between 170 μm and 425 μm, between 170 μm and 400 μm, between 170 μm and 375 μm, between 170 μm and 350 μm, between 170 μm and 325 μm, between 170 μm and 300 μm, between 170 μm and 275 μm, between 170 μm and 250 μm, between 170 μm and 225 μm, between 170 μm and 200 μm, between 170 μm and 175 μm, between 190 μm and 975 μm, between 190 μm and 950 μm, between 190 μm and 925 μm, between 190 μm and 900 μm, between 190 μm and 875 μm, between 190 μm and 850 μm, between 190 μm and 825 μm, between 190 μm and 800 μm, between 190 μm and 775 μm, between 190 μm and 750 μm, between 190 μm and 725 μm, between 190 μm and 700 μm, between 190 μm and 675 μm, between 190 μm and 650 μm, between 190 μm and 625 μm, between 190 μm and 600 μm, between 190 μm and 575 μm, between 190 μm and 550 μm, between 190 μm and 525 μm, between 190 μm and 500 μm, between 190 μm and 475 μm, between 190 μm and 450 μm, between 190 μm and 425 μm, between 190 μm and 400 μm, between 190 μm and 375 μm, between 190 μm and 350 μm, between 190 μm and 325 μm, between 190 μm and 300 μm, between 190 μm and 275 μm, between 190 μm and 250 μm, between 190 μm and 225 μm, between 190 μm and 200 μm, between 210 μm and 975 μm, between 210 μm and 950 μm, between 210 μm and 925 μm, between 210 μm and 900 μm, between 210 μm and 875 μm, between 210 μm and 850 μm, between 210 μm and 825 μm, between 210 μm and 800 μm, between 210 μm and 775 μm, between 210 μm and 750 μm, between 210 μm and 725 μm, between 210 μm and 700 μm, between 210 μm and 675 μm, between 210 μm and 650 μm, between 210 μm and 625 μm, between 210 μm and 600 μm, between 210 μm and 575 μm, between 210 μm and 550 μm, between 210 μm and 525 μm, between 210 μm and 500 μm, between 210 μm and 475 μm, between 210 μm and 450 μm, between 210 μm and 425 μm, between 210 μm and 400 μm, between 210 μm and 375 μm, between 210 μm and 350 μm, between 210 μm and 325 μm, between 210 μm and 300 μm, between 210 μm and 275 μm, between 210 μm and 250 μm, between 210 μm and 225 μm, between 230 μm and 975 μm, between 230 μm and 950 μm, between 230 μm and 925 μm, between 230 μm and 900 μm, between 230 μm and 875 μm, between 230 μm and 850 μm, between 230 μm and 825 μm, between 230 μm and 800 μm, between 230 μm and 775 μm, between 230 μm and 750 μm, between 230 μm and 725 μm, between 230 μm and 700 μm, between 230 μm and 675 μm, between 230 μm and 650 μm, between 230 μm and 625 μm, between 230 μm and 600 μm, between 230 μm and 575 μm, between 230 μm and 550 μm, between 230 μm and 525 μm, between 230 μm and 500 μm, between 230 μm and 475 μm, between 230 μm and 450 μm, between 230 μm and 425 μm, between 230 μm and 400 μm, between 230 μm and 375 μm, between 230 μm and 350 μm, between 230 μm and 325 μm, between 230 μm and 300 μm, between 230 μm and 275 μm, between 230 μm and 250 μm, between 250 μm and 975 μm, between 250 μm and 950 μm, between 250 μm and 925 μm, between 250 μm and 900 μm, between 250 μm and 875 μm, between 250 μm and 850 μm, between 250 μm and 825 μm, between 250 μm and 800 μm, between 250 μm and 775 μm, between 250 μm and 750 μm, between 250 μm and 725 μm, between 250 μm and 700 μm, between 250 μm and 675 μm, between 250 μm and 650 μm, between 250 μm and 625 μm, between 250 μm and 600 μm, between 250 μm and 575 μm, between 250 μm and 550 μm, between 250 μm and 525 μm, between 250 μm and 500 μm, between 250 μm and 475 μm, between 250 μm and 450 μm, between 250 μm and 425 μm, between 250 μm and 400 μm, between 250 μm and 375 μm, between 250 μm and 350 μm, between 250 μm and 325 μm, between 250 μm and 300 μm, between 250 μm and 275 μm, between 270 μm and 975 μm, between 270 μm and 950 μm, between 270 μm and 925 μm, between 270 μm and 900 μm, between 270 μm and 875 μm, between 270 μm and 850 μm, between 270 μm and 825 μm, between 270 μm and 800 μm, between 270 μm and 775 μm, between 270 μm and 750 μm, between 270 μm and 725 μm, between 270 μm and 700 μm, between 270 μm and 675 μm, between 270 μm and 650 μm, between 270 μm and 625 μm, between 270 μm and 600 μm, between 270 μm and 575 μm, between 270 μm and 550 μm, between 270 μm and 525 μm, between 270 μm and 500 μm, between 270 μm and 475 μm, between 270 μm and 450 μm, between 270 μm and 425 μm, between 270 μm and 400 μm, between 270 μm and 375 μm, between 270 μm and 350 μm, between 270 μm and 325 μm, between 270 μm and 300 μm, between 270 μm and 275 μm, between 290 μm and 975 μm, between 290 μm and 950 μm, between 290 μm and 925 μm, between 290 μm and 900 μm, between 290 μm and 875 μm, between 290 μm and 850 μm, between 290 μm and 825 μm, between 290 μm and 800 μm, between 290 μm and 775 μm, between 290 μm and 750 μm, between 290 μm and 725 μm, between 290 μm and 700 μm, between 290 μm and 675 μm, between 290 μm and 650 μm, between 290 μm and 625 μm, between 290 μm and 600 μm, between 290 μm and 575 μm, between 290 μm and 550 μm, between 290 μm and 525 μm, between 290 μm and 500 μm, between 290 μm and 475 μm, between 290 μm and 450 μm, between 290 μm and 425 μm, between 290 μm and 400 μm, between 290 μm and 375 μm, between 290 μm and 350 μm, between 290 μm and 325 μm, between 290 μm and 300 μm, between 310 μm and 975 μm, between 310 μm and 950 μm, between 310 μm and 925 μm, between 310 μm and 900 μm, between 310 μm and 875 μm, between 310 μm and 850 μm, between 310 μm and 825 μm, between 310 μm and 800 μm, between 310 μm and 775 μm, between 310 μm and 750 μm, between 310 μm and 725 μm, between 310 μm and 700 μm, between 310 μm and 675 μm, between 310 μm and 650 μm, between 310 μm and 625 μm, between 310 μm and 600 μm, between 310 μm and 575 μm, between 310 μm and 550 μm, between 310 μm and 525 μm, between 310 μm and 500 μm, between 310 μm and 475 μm, between 310 μm and 450 μm, between 310 μm and 425 μm, between 310 μm and 400 μm, between 310 μm and 375 μm, between 310 μm and 350 μm, between 310 μm and 325 μm, between 330 μm and 975 μm, between 330 μm and 950 μm, between 330 μm and 925 μm, between 330 μm and 900 μm, between 330 μm and 875 μm, between 330 μm and 850 μm, between 330 μm and 825 μm, between 330 μm and 800 μm, between 330 μm and 775 μm, between 330 μm and 750 μm, between 330 μm and 725 μm, between 330 μm and 700 μm, between 330 μm and 675 μm, between 330 μm and 650 μm, between 330 μm and 625 μm, between 330 μm and 600 μm, between 330 μm and 575 μm, between 330 μm and 550 μm, between 330 μm and 525 μm, between 330 μm and 500 μm, between 330 μm and 475 μm, between 330 μm and 450 μm, between 330 μm and 425 μm, between 330 μm and 400 μm, between 330 μm and 375 μm, between 330 μm and 350 μm, between 350 μm and 975 μm, between 350 μm and 950 μm, between 350 μm and 925 μm, between 350 μm and 900 μm, between 350 μm and 875 μm, between 350 μm and 850 μm, between 350 μm and 825 μm, between 350 μm and 800 μm, between 350 μm and 775 μm, between 350 μm and 750 μm, between 350 μm and 725 μm, between 350 μm and 700 μm, between 350 μm and 675 μm, between 350 μm and 650 μm, between 350 μm and 625 μm, between 350 μm and 600 μm, between 350 μm and 575 μm, between 350 μm and 550 μm, between 350 μm and 525 μm, between 350 μm and 500 μm, between 350 μm and 475 μm, between 350 μm and 450 μm, between 350 μm and 425 μm, between 350 μm and 400 μm, between 350 μm and 375 μm, between 370 μm and 975 μm, between 370 μm and 950 μm, between 370 μm and 925 μm, between 370 μm and 900 μm, between 370 μm and 875 μm, between 370 μm and 850 μm, between 370 μm and 825 μm, between 370 μm and 800 μm, between 370 μm and 775 μm, between 370 μm and 750 μm, between 370 μm and 725 μm, between 370 μm and 700 μm, between 370 μm and 675 μm, between 370 μm and 650 μm, between 370 μm and 625 μm, between 370 μm and 600 μm, between 370 μm and 575 μm, between 370 μm and 550 μm, between 370 μm and 525 μm, between 370 μm and 500 μm, between 370 μm and 475 μm, between 370 μm and 450 μm, between 370 μm and 425 μm, between 370 μm and 400 μm, between 370 μm and 375 μm, between 390 μm and 975 μm, between 390 μm and 950 μm, between 390 μm and 925 μm, between 390 μm and 900 μm, between 390 μm and 875 μm, between 390 μm and 850 μm, between 390 μm and 825 μm, between 390 μm and 800 μm, between 390 μm and 775 μm, between 390 μm and 750 μm, between 390 μm and 725 μm, between 390 μm and 700 μm, between 390 μm and 675 μm, between 390 μm and 650 μm, between 390 μm and 625 μm, between 390 μm and 600 μm, between 390 μm and 575 μm, between 390 μm and 550 μm, between 390 μm and 525 μm, between 390 μm and 500 μm, between 390 μm and 475 μm, between 390 μm and 450 μm, between 390 μm and 425 μm, between 390 μm and 400 μm, between 410 μm and 975 μm, between 410 μm and 950 μm, between 410 μm and 925 μm, between 410 μm and 900 μm, between 410 μm and 875 μm, between 410 μm and 850 μm, between 410 μm and 825 μm, between 410 μm and 800 μm, between 410 μm and 775 μm, between 410 μm and 750 μm, between 410 μm and 725 μm, between 410 μm and 700 μm, between 410 μm and 675 μm, between 410 μm and 650 μm, between 410 μm and 625 μm, between 410 μm and 600 μm, between 410 μm and 575 μm, between 410 μm and 550 μm, between 410 μm and 525 μm, between 410 μm and 500 μm, between 410 μm and 475 μm, between 410 μm and 450 μm, between 410 μm and 425 μm, between 410 μm and 400 μm, between 430 μm and 975 μm, between 430 μm and 950 μm, between 430 μm and 925 μm, between 430 μm and 900 μm, between 430 μm and 875 μm, between 430 μm and 850 μm, between 430 μm and 825 μm, between 430 μm and 800 μm, between 430 μm and 775 μm, between 430 μm and 750 μm, between 430 μm and 725 μm, between 430 μm and 700 μm, between 430 μm and 675 μm, between 430 μm and 650 μm, between 430 μm and 625 μm, between 430 μm and 600 μm, between 430 μm and 575 μm, between 430 μm and 550 μm, between 430 μm and 525 μm, between 430 μm and 500 μm, between 430 μm and 475 μm, between 430 μm and 450 μm, between 450 μm and 975 μm, between 450 μm and 950 μm, between 450 μm and 925 μm, between 450 μm and 900 μm, between 450 μm and 875 μm, between 450 μm and 850 μm, between 450 μm and 825 μm, between 450 μm and 800 μm, between 450 μm and 775 μm, between 450 μm and 750 μm, between 450 μm and 725 μm, between 450 μm and 700 μm, between 450 μm and 675 μm, between 450 μm and 650 μm, between 450 μm and 625 μm, between 450 μm and 600 μm, between 450 μm and 575 μm, between 450 μm and 550 μm, between 450 μm and 525 μm, between 450 μm and 500 μm, between 450 μm and 475 μm, between 470 μm and 975 μm, between 470 μm and 950 μm, between 470 μm and 925 μm, between 470 μm and 900 μm, between 470 μm and 875 μm, between 470 μm and 850 μm, between 470 μm and 825 μm, between 470 μm and 800 μm, between 470 μm and 775 μm, between 470 μm and 750 μm, between 470 μm and 725 μm, between 470 μm and 700 μm, between 470 μm and 675 μm, between 470 μm and 650 μm, between 470 μm and 625 μm, between 470 μm and 600 μm, between 470 μm and 575 μm, between 470 μm and 550 μm, between 470 μm and 525 μm, between 470 μm and 500 μm, between 470 μm and 475 μm, between 490 μm and 975 μm, between 490 μm and 950 μm, between 490 μm and 925 μm, between 490 μm and 900 μm, between 490 μm and 875 μm, between 490 μm and 850 μm, between 490 μm and 825 μm, between 490 μm and 800 μm, between 490 μm and 775 μm, between 490 μm and 750 μm, between 490 μm and 725 μm, between 490 μm and 700 μm, between 490 μm and 675 μm, between 490 μm and 650 μm, between 490 μm and 625 μm, between 490 μm and 600 μm, between 490 μm and 575 μm, between 490 μm and 550 μm, between 490 μm and 525 μm, between 490 μm and 500 μm, between 510 μm and 975 μm, between 510 μm and 950 μm, between 510 μm and 925 μm, between 510 μm and 900 μm, between 510 μm and 875 μm, between 510 μm and 850 μm, between 510 μm and 825 μm, between 510 μm and 800 μm, between 510 μm and 775 μm, between 510 μm and 750 μm, between 510 μm and 725 μm, between 510 μm and 700 μm, between 510 μm and 675 μm, between 510 μm and 650 μm, between 510 μm and 625 μm, between 510 μm and 600 μm, between 510 μm and 575 μm, between 510 μm and 550 μm, between 510 μm and 525 μm, between 530 μm and 975 μm, between 530 μm and 950 μm, between 530 μm and 925 μm, between 530 μm and 900 μm, between 530 μm and 875 μm, between 530 μm and 850 μm, between 530 μm and 825 μm, between 530 μm and 800 μm, between 530 μm and 775 μm, between 530 μm and 750 μm, between 530 μm and 725 μm, between 530 μm and 700 μm, between 530 μm and 675 μm, between 530 μm and 650 μm, between 530 μm and 625 μm, between 530 μm and 600 μm, between 530 μm and 575 μm, between 530 μm and 550 μm, between 550 μm and 975 μm, between 550 μm and 950 μm, between 550 μm and 925 μm, between 550 μm and 900 μm, between 550 μm and 875 μm, between 550 μm and 850 μm, between 550 μm and 825 μm, between 550 μm and 800 μm, between 550 μm and 775 μm, between 550 μm and 750 μm, between 550 μm and 725 μm, between 550 μm and 700 μm, between 550 μm and 675 μm, between 550 μm and 650 μm, between 550 μm and 625 μm, between 550 μm and 600 μm, between 550 μm and 575 μm, between 570 μm and 975 μm, between 570 μm and 950 μm, between 570 μm and 925 μm, between 570 μm and 900 μm, between 570 μm and 875 μm, between 570 μm and 850 μm, between 570 μm and 825 μm, between 570 μm and 800 μm, between 570 μm and 775 μm, between 570 μm and 750 μm, between 570 μm and 725 μm, between 570 μm and 700 μm, between 570 μm and 675 μm, between 570 μm and 650 μm, between 570 μm and 625 μm, between 570 μm and 600 μm, between 570 μm and 575 μm, between 590 μm and 975 μm, between 590 μm and 950 μm, between 590 μm and 925 μm, between 590 μm and 900 μm, between 590 μm and 875 μm, between 590 μm and 850 μm, between 590 μm and 825 μm, between 590 μm and 800 μm, between 590 μm and 775 μm, between 590 μm and 750 μm, between 590 μm and 725 μm, between 590 μm and 700 μm, between 590 μm and 675 μm, between 590 μm and 650 μm, between 590 μm and 625 μm, between 590 μm and 600 μm, between 610 μm and 975 μm, between 610 μm and 950 μm, between 610 μm and 925 μm, between 610 μm and 900 μm, between 610 μm and 875 μm, between 610 μm and 850 μm, between 610 μm and 825 μm, between 610 μm and 800 μm, between 610 μm and 775 μm, between 610 μm and 750 μm, between 610 μm and 725 μm, between 610 μm and 700 μm, between 610 μm and 675 μm, between 610 μm and 650 μm, between 610 μm and 625 μm, between 630 μm and 975 μm, between 630 μm and 950 μm, between 630 μm and 925 μm, between 630 μm and 900 μm, between 630 μm and 875 μm, between 630 μm and 850 μm, between 630 μm and 825 μm, between 630 μm and 800 μm, between 630 μm and 775 μm, between 630 μm and 750 μm, between 630 μm and 725 μm, between 630 μm and 700 μm, between 630 μm and 675 μm, between 630 μm and 650 μm, between 650 μm and 975 μm, between 650 μm and 950 μm, between 650 μm and 925 μm, between 650 μm and 900 μm, between 650 μm and 875 μm, between 650 μm and 850 μm, between 650 μm and 825 μm, between 650 μm and 800 μm, between 650 μm and 775 μm, between 650 μm and 750 μm, between 650 μm and 725 μm, between 650 μm and 700 μm, between 650 μm and 675 μm, between 670 μm and 975 μm, between 670 μm and 950 μm, between 670 μm and 925 μm, between 670 μm and 900 μm, between 670 μm and 875 μm, between 670 μm and 850 μm, between 670 μm and 825 μm, between 670 μm and 800 μm, between 670 μm and 775 μm, between 670 μm and 750 μm, between 670 μm and 725 μm, between 670 μm and 700 μm, between 670 μm and 675 μm, between 690 μm and 975 μm, between 690 μm and 950 μm, between 690 μm and 925 μm, between 690 μm and 900 μm, between 690 μm and 875 μm, between 690 μm and 850 μm, between 690 μm and 825 μm, between 690 μm and 800 μm, between 690 μm and 775 μm, between 690 μm and 750 μm, between 690 μm and 725 μm, between 690 μm and 700 μm, between 710 μm and 975 μm, between 710 μm and 950 μm, between 710 μm and 925 μm, between 710 μm and 900 μm, between 710 μm and 875 μm, between 710 μm and 850 μm, between 710 μm and 825 μm, between 710 μm and 800 μm, between 710 μm and 775 μm, between 710 μm and 750 μm, between 710 μm and 725 μm, between 730 μm and 975 μm, between 730 μm and 950 μm, between 730 μm and 925 μm, between 730 μm and 900 μm, between 730 μm and 875 μm, between 730 μm and 850 μm, between 730 μm and 825 μm, between 730 μm and 800 μm, between 730 μm and 775 μm, between 730 μm and 750 μm, between 750 μm and 975 μm, between 750 μm and 950 μm, between 750 μm and 925 μm, between 750 μm and 900 μm, between 750 μm and 875 μm, between 750 μm and 850 μm, between 750 μm and 825 μm, between 750 μm and 800 μm, between 750 μm and 775 μm, between 770 μm and 975 μm, between 770 μm and 950 μm, between 770 μm and 925 μm, between 770 μm and 900 μm, between 770 μm and 875 μm, between 770 μm and 850 μm, between 770 μm and 825 μm, between 770 μm and 800 μm, between 770 μm and 775 μm, between 790 μm and 975 μm, between 790 μm and 950 μm, between 790 μm and 925 μm, between 790 μm and 900 μm, between 790 μm and 875 μm, between 790 μm and 850 μm, between 790 μm and 825 μm, between 790 μm and 800 μm, between 810 μm and 975 μm, between 810 μm and 950 μm, between 810 μm and 925 μm, between 810 μm and 900 μm, between 810 μm and 875 μm, between 810 μm and 850 μm, between 810 μm and 825 μm, between 830 μm and 975 μm, between 830 μm and 950 μm, between 830 μm and 925 μm, between 830 μm and 900 μm, between 830 μm and 875 μm, between 830 μm and 850 μm, between 850 μm and 975 μm, between 850 μm and 950 μm, between 850 μm and 925 μm, between 850 μm and 900 μm, between 850 μm and 875 μm, between 870 μm and 975 μm, between 870 μm and 950 μm, between 870 μm and 925 μm, between 870 μm and 900 μm, between 870 μm and 875 μm, between 890 μm and 975 μm, between 890 μm and 950 μm, between 890 μm and 925 μm, between 890 μm and 900 μm, between 910 μm and 975 μm, between 910 μm and 950 μm, between 910 μm and 925 μm, between 930 μm and 975 μm, between 930 μm and 950 μm, between 950 μm and 975 μm, or between 970 μm and 975 μm.

In some embodiments, the nominal diameter or a width of a cross-section of a via is at least 5 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, at least 500 μm, at least 505 μm, at least 510 μm, at least 515 μm, at least 520 μm, at least 525 μm, at least 530 μm, at least 535 μm, at least 540 μm, at least 545 μm, at least 550 μm, at least 555 μm, at least 560 μm, at least 565 μm, at least 570 μm, at least 575 μm, at least 580 μm, at least 585 μm, at least 590 μm, at least 595 μm, at least 600 μm, at least 605 μm, at least 610 μm, at least 615 μm, at least 620 μm, at least 625 μm, at least 630 μm, at least 635 μm, at least 640 μm, at least 645 μm, at least 650 μm, at least 655 μm, at least 660 μm, at least 665 μm, at least 670 μm, at least 675 μm, at least 680 μm, at least 685 μm, at least 690 μm, at least 695 μm, at least 700 μm, at least 705 μm, at least 710 μm, at least 715 μm, at least 720 μm, at least 725 μm, at least 730 μm, at least 735 μm, at least 740 μm, at least 745 μm, at least 750 μm, at least 755 μm, at least 760 μm, at least 765 μm, at least 770 μm, at least 775 μm, at least 780 μm, at least 785 μm, at least 790 μm, at least 795 μm, at least 800 μm, at least 805 μm, at least 810 μm, at least 815 μm, at least 820 μm, at least 825 μm, at least 830 μm, at least 835 μm, at least 840 μm, at least 845 μm, at least 850 μm, at least 855 μm, at least 860 μm, at least 865 μm, at least 870 μm, at least 875 μm, at least 880 μm, at least 885 μm, at least 890 μm, at least 895 μm, at least 900 μm, at least 905 μm, at least 910 μm, at least 915 μm, at least 920 μm, at least 925 μm, at least 930 μm, at least 935 μm, at least 940 μm, at least 945 μm, at least 950 μm, at least 955 μm, at least 960 μm, at least 965 μm, at least 970 μm, at least 975 μm, at least 980 μm, at least 985 μm, at least 990 μm, at least 995 μm, or at least 1,000 μm.

In some embodiments, the nominal diameter or a width of a cross-section of the via is at most 5 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, at most 500 μm, at most 505 μm, at most 510 μm, at most 515 μm, at most 520 μm, at most 525 μm, at most 530 μm, at most 535 μm, at most 540 μm, at most 545 μm, at most 550 μm, at most 555 μm, at most 560 μm, at most 565 μm, at most 570 μm, at most 575 μm, at most 580 μm, at most 585 μm, at most 590 μm, at most 595 μm, at most 600 μm, at most 605 μm, at most 610 μm, at most 615 μm, at most 620 μm, at most 625 μm, at most 630 μm, at most 635 μm, at most 640 μm, at most 645 μm, at most 650 μm, at most 655 μm, at most 660 μm, at most 665 μm, at most 670 μm, at most 675 μm, at most 680 μm, at most 685 μm, at most 690 μm, at most 695 μm, at most 700 μm, at most 705 μm, at most 710 μm, at most 715 μm, at most 720 μm, at most 725 μm, at most 730 μm, at most 735 μm, at most 740 μm, at most 745 μm, at most 750 μm, at most 755 μm, at most 760 μm, at most 765 μm, at most 770 μm, at most 775 μm, at most 780 μm, at most 785 μm, at most 790 μm, at most 795 μm, at most 800 μm, at most 805 μm, at most 810 μm, at most 815 μm, at most 820 μm, at most 825 μm, at most 830 μm, at most 835 μm, at most 840 μm, at most 845 μm, at most 850 μm, at most 855 μm, at most 860 μm, at most 865 μm, at most 870 μm, at most 875 μm, at most 880 μm, at most 885 μm, at most 890 μm, at most 895 μm, at most 900 μm, at most 905 μm, at most 910 μm, at most 915 μm, at most 920 μm, at most 925 μm, at most 930 μm, at most 935 μm, at most 940 μm, at most 945 μm, at most 950 μm, at most 955 μm, at most 960 μm, at most 965 μm, at most 970 μm, at most 975 μm, at most 980 μm, at most 985 μm, at most 990 μm, at most 995 μm, or at least 1,000 μm.

In some embodiments, the nominal diameter or a width of a cross-section of a via is between 0.1 mil and 40 mil, between 0.2 mil and 40 mil, between 0.2 mil and 35 mil, between 0.2 and 30 mil, between 0.2 mil and 25 mil, between 0.2 and 20 mil, between 0.2 mil and 15 mil, between 0.2 and 10 mil, between 0.2 mil and 5 mil, between 0.2 and 1 mil, between 0.4 mil and 40 mil, between 0.4 mil and 35 mil, between 0.4 and 30 mil, between 0.4 mil and 25 mil, between 0.4 and 20 mil, between 0.4 mil and 15 mil, between 0.4 and 10 mil, between 0.4 mil and 5 mil, between 0.4 and 1 mil, between 0.6 mil and 40 mil, between 0.6 mil and 35 mil, between 0.6 and 30 mil, between 0.6 mil and 25 mil, between 0.6 and 20 mil, between 0.6 mil and 15 mil, between 0.6 and 10 mil, between 0.6 mil and 5 mil, between 0.6 and 1 mil, between 0.8 mil and 40 mil, between 0.8 mil and 35 mil, between 0.8 and 30 mil, between 0.8 mil and 25 mil, between 0.8 and 20 mil, between 0.8 mil and 15 mil, between 0.8 and 10 mil, between 0.8 mil and 5 mil, between 0.8 and 1 mil, between 1.2 mil and 40 mil, between 1.2 mil and 35 mil, between 1.2 and 30 mil, between 1.2 mil and 25 mil, between 1.2 and 20 mil, between 1.2 mil and 15 mil, between 1.2 and 10 mil, between 1.2 mil and 5 mil, between 1.2 and 3 mil, between 1.7 mil and 40 mil, between 1.7 mil and 35 mil, between 1.7 and 30 mil, between 1.7 mil and 25 mil, between 1.7 and 20 mil, between 1.7 mil and 15 mil, between 1.7 and 10 mil, between 1.7 mil and 5 mil, between 1.7 and 3 mil, between 2.2 mil and 40 mil, between 2.2 mil and 35 mil, between 2.2 and 30 mil, between 2.2 mil and 25 mil, between 2.2 and 20 mil, between 2.2 mil and 15 mil, between 2.2 and 10 mil, between 2.2 mil and 5 mil, between 2.2 and 3 mil, between 2.7 mil and 40 mil, between 2.7 mil and 35 mil, between 2.7 and 30 mil, between 2.7 mil and 25 mil, between 2.7 and 20 mil, between 2.7 mil and 15 mil, between 2.7 and 10 mil, between 2.7 mil and 5 mil, between 2.7 and 3 mil, between 3.2 mil and 40 mil, between 3.2 mil and 35 mil, between 3.2 and 30 mil, between 3.2 mil and 25 mil, between 3.2 and 20 mil, between 3.2 mil and 15 mil, between 3.2 and 10 mil, between 3.2 mil and 5 mil, between 3.7 mil and 40 mil, between 3.7 mil and 35 mil, between 3.7 and 30 mil, between 3.7 mil and 25 mil, between 3.7 and 20 mil, between 3.7 mil and 15 mil, between 3.7 and 10 mil, between 3.7 mil and 5 mil, between 4.2 mil and 40 mil, between 4.2 mil and 35 mil, between 4.2 and 30 mil, between 4.2 mil and 25 mil, between 4.2 and 20 mil, between 4.2 mil and 15 mil, between 4.2 and 10 mil, between 4.2 mil and 5 mil, between 4.7 mil and 40 mil, between 4.7 mil and 35 mil, between 4.7 and 30 mil, between 4.7 mil and 25 mil, between 4.7 and 20 mil, between 4.7 mil and 15 mil, between 4.7 and 10 mil, between 4.7 mil and 5 mil, between 5.2 mil and 40 mil, between 5.2 mil and 35 mil, between 5.2 and 30 mil, between 5.2 mil and 25 mil, between 5.2 and 20 mil, between 5.2 mil and 15 mil, between 5.2 and 10 mil, between 5.7 mil and 40 mil, between 5.7 mil and 35 mil, between 5.7 and 30 mil, between 5.7 mil and 25 mil, between 5.7 and 20 mil, between 5.7 mil and 15 mil, between 5.7 and 10 mil, between 6.2 mil and 40 mil, between 6.2 mil and 35 mil, between 6.2 and 30 mil, between 6.2 mil and 25 mil, between 6.2 and 20 mil, between 6.2 mil and 15 mil, between 6.2 and 10 mil, between 6.7 mil and 40 mil, between 6.7 mil and 35 mil, between 6.7 and 30 mil, between 6.7 mil and 25 mil, between 6.7 and 20 mil, between 6.7 mil and 15 mil, between 6.7 and 10 mil, between 7.2 mil and 40 mil, between 7.2 mil and 35 mil, between 7.2 and 30 mil, between 7.2 mil and 25 mil, between 7.2 and 20 mil, between 7.2 mil and 15 mil, between 7.2 and 10 mil, between 7.7 mil and 40 mil, between 7.7 mil and 35 mil, between 7.7 and 30 mil, between 7.7 mil and 25 mil, between 7.7 and 20 mil, between 7.7 mil and 15 mil, between 7.7 and 10 mil, between 8.2 mil and 40 mil, between 8.2 mil and 35 mil, between 8.2 and 30 mil, between 8.2 mil and 25 mil, between 8.2 and 20 mil, between 8.2 mil and 15 mil, between 8.2 and 10 mil, between 8.7 mil and 40 mil, between 8.7 mil and 35 mil, between 8.7 and 30 mil, between 8.7 mil and 25 mil, between 8.7 and 20 mil, between 8.7 mil and 15 mil, between 8.7 and 10 mil, between 9.2 mil and 40 mil, between 9.2 mil and 35 mil, between 9.2 and 30 mil, between 9.2 mil and 25 mil, between 9.2 and 20 mil, between 9.2 mil and 15 mil, between 9.2 and 10 mil, between 9.7 mil and 40 mil, between 9.7 mil and 35 mil, between 9.7 and 30 mil, between 9.7 mil and 25 mil, between 9.7 and 20 mil, between 9.7 mil and 15 mil, between 9.7 and 10 mil, between 11.2 mil and 40 mil, between 11.2 mil and 35 mil, between 11.2 and 30 mil, between 11.2 mil and 25 mil, between 11.2 and 20 mil, between 11.2 mil and 15 mil, between 11.7 mil and 40 mil, between 11.7 mil and 35 mil, between 11.7 and 30 mil, between 11.7 mil and 25 mil, between 11.7 and 20 mil, between 11.7 mil and 15 mil, between 12.2 mil and 40 mil, between 12.2 mil and 35 mil, between 12.2 and 30 mil, between 12.2 mil and 25 mil, between 12.2 and 20 mil, between 12.2 mil and 15 mil, between 12.7 mil and 40 mil, between 12.7 mil and 35 mil, between 12.7 and 30 mil, between 12.7 mil and 25 mil, between 12.7 and 20 mil, between 12.7 mil and 15 mil, between 13.2 mil and 40 mil, between 13.2 mil and 35 mil, between 13.2 and 30 mil, between 13.2 mil and 25 mil, between 13.2 and 20 mil, between 13.2 mil and 15 mil, between 13.7 mil and 40 mil, between 13.7 mil and 35 mil, between 13.7 and 30 mil, between 13.7 mil and 25 mil, between 13.7 and 20 mil, between 13.7 mil and 15 mil, between 14.2 mil and 40 mil, between 14.2 mil and 35 mil, between 14.2 and 30 mil, between 14.2 mil and 25 mil, between 14.2 and 20 mil, between 14.2 mil and 15 mil, between 14.7 mil and 40 mil, between 14.7 mil and 35 mil, between 14.7 and 30 mil, between 14.7 mil and 25 mil, between 14.7 and 20 mil, between 14.7 mil and 15 mil, between 15.2 mil and 40 mil, between 15.2 mil and 35 mil, between 15.2 and 30 mil, between 15.2 mil and 25 mil, between 15.2 and 20 mil, between 15.7 mil and 40 mil, between 15.7 mil and 35 mil, between 15.7 and 30 mil, between 15.7 mil and 25 mil, between 15.7 and 20 mil, between 16.2 mil and 40 mil, between 16.2 mil and 35 mil, between 16.2 and 30 mil, between 16.2 mil and 25 mil, between 16.2 and 20 mil, between 16.7 mil and 40 mil, between 16.7 mil and 35 mil, between 16.7 and 30 mil, between 16.7 mil and 25 mil, between 16.7 and 20 mil, between 17.2 mil and 40 mil, between 17.2 mil and 35 mil, between 17.2 and 30 mil, between 17.2 mil and 25 mil, between 17.2 and 20 mil, between 17.7 mil and 40 mil, between 17.7 mil and 35 mil, between 17.7 and 30 mil, between 17.7 mil and 25 mil, between 17.7 and 20 mil, between 18.2 mil and 40 mil, between 18.2 mil and 35 mil, between 18.2 and 30 mil, between 18.2 mil and 25 mil, between 18.2 and 20 mil, between 18.7 mil and 40 mil, between 18.7 mil and 35 mil, between 18.7 and 30 mil, between 18.7 mil and 25 mil, between 18.7 and 20 mil, between 19.2 mil and 40 mil, between 19.2 mil and 35 mil, between 19.2 and 30 mil, between 19.2 mil and 25 mil, between 19.2 and 20 mil, between 19.7 mil and 40 mil, between 19.7 mil and 35 mil, between 19.7 and 30 mil, between 19.7 mil and 25 mil, between 19.7 and 20 mil, between 21.2 mil and 40 mil, between 21.2 mil and 35 mil, between 21.2 and 30 mil, between 21.2 mil and 25 mil, between 21.7 mil and 40 mil, between 21.7 mil and 35 mil, between 21.7 and 30 mil, between 21.7 mil and 25 mil, between 22.2 mil and 40 mil, between 22.2 mil and 35 mil, between 22.2 and 30 mil, between 22.2 mil and 25 mil, between 22.7 mil and 40 mil, between 22.7 mil and 35 mil, between 22.7 and 30 mil, between 22.7 mil and 25 mil, between 23.2 mil and 40 mil, between 23.2 mil and 35 mil, between 23.2 and 30 mil, between 23.2 mil and 25 mil, between 23.7 mil and 40 mil, between 23.7 mil and 35 mil, between 23.7 and 30 mil, between 23.7 mil and 25 mil, between 24.2 mil and 40 mil, between 24.2 mil and 35 mil, between 24.2 and 30 mil, between 24.2 mil and 25 mil, between 24.7 mil and 40 mil, between 24.7 mil and 35 mil, between 24.7 and 30 mil, between 24.7 mil and 25 mil, between 25.2 mil and 40 mil, between 25.2 mil and 35 mil, between 25.2 and 30 mil, between 25.7 mil and 40 mil, between 25.7 mil and 35 mil, between 25.7 and 30 mil, between 26.2 mil and 40 mil, between 26.2 mil and 35 mil, between 26.2 and 30 mil, between 26.7 mil and 40 mil, between 26.7 mil and 35 mil, between 26.7 and 30 mil, between 27.2 mil and 40 mil, between 27.2 mil and 35 mil, between 27.2 and 30 mil, between 27.7 mil and 40 mil, between 27.7 mil and 35 mil, between 27.7 and 30 mil, between 28.2 mil and 40 mil, between 28.2 mil and 35 mil, between 28.2 and 30 mil, between 28.7 mil and 40 mil, between 28.7 mil and 35 mil, between 28.7 and 30 mil, between 29.2 mil and 40 mil, between 29.2 mil and 35 mil, between 29.2 and 30 mil, between 29.7 mil and 40 mil, between 29.7 mil and 35 mil, between 29.7 and 30 mil, between 31.2 mil and 40 mil, between 31.2 mil and 35 mil, between 31.7 mil and 40 mil, between 31.7 mil and 35 mil, between 32.2 mil and 40 mil, between 32.2 mil and 35 mil, between 32.7 mil and 40 mil, between 32.7 mil and 35 mil, between 33.2 mil and 40 mil, between 33.2 mil and 35 mil, between 33.7 mil and 40 mil, between 33.7 mil and 35 mil, between 34.2 mil and 40 mil, between 34.2 mil and 35 mil, between 34.7 mil and 40 mil, between 34.7 mil and 35 mil, between 35.2 mil and 40 mil, between 35.7 mil and 40 mil, between 36.2 mil and 40 mil, between 36.7 mil and 40 mil, between 37.2 mil and 40 mil, between 37.7 mil and 40 mil, between 38.2 mil and 40 mil, between 38.7 mil and 40 mil, between 39.2 mil and 40 mil, or between 39.7 mil and 40 mil.

In some embodiments, the nominal diameter or a width of a cross-section of a via is at least 0.1 mil, at least 0.3 mil, at least 0.6 mil, at least 0.9 mil, at least 1.1 mil, at least 1.3 mil, at least 1.6 mil, at least 1.9 mil, at least 2.1 mil, at least 2.3 mil, at least 2.6 mil, at least 2.9 mil, at least 3.1 mil, at least 3.3 mil, at least 3.6 mil, at least 3.9 mil, at least 4.1 mil, at least 4.3 mil, at least 4.6 mil, at least 4.9 mil, at least 5.1 mil, at least 5.3 mil, at least 5.6 mil, at least 5.9 mil, at least 6.1 mil, at least 6.3 mil, at least 6.6 mil, at least 6.9 mil, at least 7.1 mil, at least 7.3 mil, at least 7.6 mil, at least 7.9 mil, at least 8.1 mil, at least 8.3 mil, at least 8.6 mil, at least 8.9 mil, at least 9.1 mil, at least 9.3 mil, at least 9.6 mil, at least 9.9 mil, at least 10.1 mil, at least 10.3 mil, at least 10.6 mil, at least 10.9 mil, at least 11.1 mil, at least 11.3 mil, at least 11.6 mil, at least 11.9 mil, at least 12.1 mil, at least 12.3 mil, at least 12.6 mil, at least 12.9 mil, at least 13.1 mil, at least 13.3 mil, at least 13.6 mil, at least 13.9 mil, at least 14.1 mil, at least 14.3 mil, at least 14.6 mil, at least 14.9 mil, at least 15.1 mil, at least 15.3 mil, at least 15.6 mil, at least 15.9 mil, at least 16.1 mil, at least 16.3 mil, at least 16.6 mil, at least 16.9 mil, at least 17.1 mil, at least 17.3 mil, at least 17.6 mil, at least 17.9 mil, at least 18.1 mil, at least 18.3 mil, at least 18.6 mil, at least 18.9 mil, at least 19.1 mil, at least 19.3 mil, at least 19.6 mil, at least 19.9 mil, at least 20.1 mil, at least 20.3 mil, at least 20.6 mil, at least 20.9 mil, at least 21.1 mil, at least 21.3 mil, at least 21.6 mil, at least 21.9 mil, at least 22.1 mil, at least 22.3 mil, at least 22.6 mil, at least 22.9 mil, at least 23.1 mil, at least 23.3 mil, at least 23.6 mil, at least 23.9 mil, at least 24.1 mil, at least 24.3 mil, at least 24.6 mil, at least 24.9 mil, at least 25.1 mil, at least 25.3 mil, at least 25.6 mil, at least 25.9 mil, at least 26.1 mil, at least 26.3 mil, at least 26.6 mil, at least 26.9 mil, at least 27.1 mil, at least 27.3 mil, at least 27.6 mil, at least 27.9 mil, at least 28.1 mil, at least 28.3 mil, at least 28.6 mil, at least 28.9 mil, at least 29.1 mil, at least 29.3 mil, at least 29.6 mil, at least 29.9 mil, at least 30.1 mil, at least 30.3 mil, at least 30.6 mil, at least 30.9 mil, at least 31.1 mil, at least 31.3 mil, at least 31.6 mil, at least 31.9 mil, at least 32.1 mil, at least 32.3 mil, at least 32.6 mil, at least 32.9 mil, at least 33.1 mil, at least 33.3 mil, at least 33.6 mil, at least 33.9 mil, at least 34.1 mil, at least 34.3 mil, at least 34.6 mil, at least 34.9 mil, at least 35.1 mil, at least 35.3 mil, at least 35.6 mil, at least 35.9 mil, at least 36.1 mil, at least 36.3 mil, at least 36.6 mil, at least 36.9 mil, at least 37.1 mil, at least 37.3 mil, at least 37.6 mil, at least 37.9 mil, at least 38.1 mil, at least 38.3 mil, at least 38.6 mil, at least 38.9 mil, at least 39.1 mil, at least 39.3 mil, at least 39.6 mil, or at least 39.9 mil.

In some embodiments, the nominal diameter of the via is at most 0.1 mil, at most 0.3 mil, at most 0.6 mil, at most 0.9 mil, at most 1.1 mil, at most 1.3 mil, at most 1.6 mil, at most 1.9 mil, at most 2.1 mil, at most 2.3 mil, at most 2.6 mil, at most 2.9 mil, at most 3.1 mil, at most 3.3 mil, at most 3.6 mil, at most 3.9 mil, at most 4.1 mil, at most 4.3 mil, at most 4.6 mil, at most 4.9 mil, at most 5.1 mil, at most 5.3 mil, at most 5.6 mil, at most 5.9 mil, at most 6.1 mil, at most 6.3 mil, at most 6.6 mil, at most 6.9 mil, at most 7.1 mil, at most 7.3 mil, at most 7.6 mil, at most 7.9 mil, at most 8.1 mil, at most 8.3 mil, at most 8.6 mil, at most 8.9 mil, at most 9.1 mil, at most 9.3 mil, at most 9.6 mil, at most 9.9 mil, at most 10.1 mil, at most 10.3 mil, at most 10.6 mil, at most 10.9 mil, at most 11.1 mil, at most 11.3 mil, at most 11.6 mil, at most 11.9 mil, at most 12.1 mil, at most 12.3 mil, at most 12.6 mil, at most 12.9 mil, at most 13.1 mil, at most 13.3 mil, at most 13.6 mil, at most 13.9 mil, at most 14.1 mil, at most 14.3 mil, at most 14.6 mil, at most 14.9 mil, at most 15.1 mil, at most 15.3 mil, at most 15.6 mil, at most 15.9 mil, at most 16.1 mil, at most 16.3 mil, at most 16.6 mil, at most 16.9 mil, at most 17.1 mil, at most 17.3 mil, at most 17.6 mil, at most 17.9 mil, at most 18.1 mil, at most 18.3 mil, at most 18.6 mil, at most 18.9 mil, at most 19.1 mil, at most 19.3 mil, at most 19.6 mil, at most 19.9 mil, at most 20.1 mil, at most 20.3 mil, at most 20.6 mil, at most 20.9 mil, at most 21.1 mil, at most 21.3 mil, at most 21.6 mil, at most 21.9 mil, at most 22.1 mil, at most 22.3 mil, at most 22.6 mil, at most 22.9 mil, at most 23.1 mil, at most 23.3 mil, at most 23.6 mil, at most 23.9 mil, at most 24.1 mil, at most 24.3 mil, at most 24.6 mil, at most 24.9 mil, at most 25.1 mil, at most 25.3 mil, at most 25.6 mil, at most 25.9 mil, at most 26.1 mil, at most 26.3 mil, at most 26.6 mil, at most 26.9 mil, at most 27.1 mil, at most 27.3 mil, at most 27.6 mil, at most 27.9 mil, at most 28.1 mil, at most 28.3 mil, at most 28.6 mil, at most 28.9 mil, at most 29.1 mil, at most 29.3 mil, at most 29.6 mil, at most 29.9 mil, at most 30.1 mil, at most 30.3 mil, at most 30.6 mil, at most 30.9 mil, at most 31.1 mil, at most 31.3 mil, at most 31.6 mil, at most 31.9 mil, at most 32.1 mil, at most 32.3 mil, at most 32.6 mil, at most 32.9 mil, at most 33.1 mil, at most 33.3 mil, at most 33.6 mil, at most 33.9 mil, at most 34.1 mil, at most 34.3 mil, at most 34.6 mil, at most 34.9 mil, at most 35.1 mil, at most 35.3 mil, at most 35.6 mil, at most 35.9 mil, at most 36.1 mil, at most 36.3 mil, at most 36.6 mil, at most 36.9 mil, at most 37.1 mil, at most 37.3 mil, at most 37.6 mil, at most 37.9 mil, at most 38.1 mil, at most 38.3 mil, at most 38.6 mil, at most 38.9 mil, at most 39.1 mil, at most 39.3 mil, at most 39.6 mil, or at most 39.9 mil.

The third electrically-conductive component 230 has a first end portion 232 and a second end portion 234. The first end portion 232 forms a first interface 242 with the first electrically-conductive component 210. Similarly, the second end portion 234 forms a second interface 244 with the second electrically-conductive component 220. As used herein, the term “interface” refers to a shared boundary across which two or more separate components meet and interact. For instance, the first interface 242 is the shared boundary across which the first and third electrically-conductive components meet and interact. The second interface 244 is the shared boundary across which the second and third electrically-conductive components meet and interact.

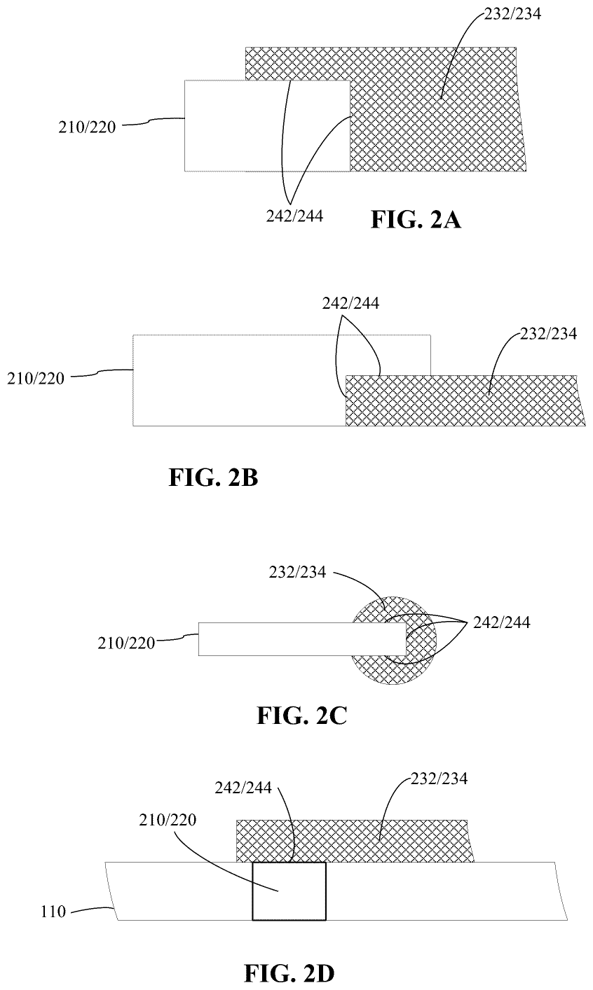

An interface between two electrically-conductive components can be formed in a variety of ways with varying configurations (e.g., shapes, sizes). For instance, as a non-limiting example, FIG. 2A is a cross-sectional view schematically illustrating an embodiment where the third electrically-conductive component 230 (e.g., a line) has the first end portion 232 partially disposed on top of the first electrically-conductive component 210 (e.g., a metallic pad) or the second end portion 234 partially disposed on the second electrically-conductive component 220 (e.g., a metallic pad). As another non-limiting example, FIG. 2B is a cross-sectional view schematically illustrating an embodiment where the third electrically-conductive component 230 (e.g., a line) has the first end portion 232 partially covered by the first electrically-conductive component 210 (e.g., a line) or the second end portion 234 partially covered by the second electrically-conductive component 220 (e.g., a line). As a further non-limiting example, FIG. 2C is a top view schematically illustrating an embodiment where the third electrically-conductive component 230 (e.g., a via) has the first end portion 232 partially covered by the first electrically-conductive component 210 (e.g., a line, a pad) or the second end portion 234 partially covered by the second electrically-conductive component 220 (e.g., a line, a pad). As a further non-limiting example, FIG. 2D is a cross-sectional view schematically illustrating an embodiment where the third electrically-conductive component 230 (e.g., a line) has the first end portion 232 partially disposed on the first electrically-conductive component 210 (e.g., a via) or the second end portion 234 partially disposed on the second electrically-conductive component 220 (e.g., a via).

In some embodiments, the thickness of the interface is between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the thickness of the interface changes as a function of length and/or depth of the interface. For instance, in some embodiments, the width of the interface is at least 1, 2, 3, 5, 10, 15, 20, or 25 percent larger at one point in the length of the interface as it is at a second point in the length of the interface. In some embodiments, the first point in the length of the interface is the first point at which the interface has the largest cross-section and the second point is the point at which the interface has the smallest cross-section. In some embodiments, the in thickness of the interface does not appreciably or measurably change as a function of length and/or depth of the interface.

In some embodiments, the thickness of the interface is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the thickness of the interface is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

In some embodiments, the width of the interface is between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the width of the interface changes as a function of length and/or depth of the interface. For instance, in some embodiments, the width of the interface is at least 1, 2, 3, 5, 10, 15, 20, or 25 percent larger at one point in the length of the interface as it is at a second point in the length of the interface. In some embodiments, the first point in the length of the interface is the first point at which the interface has the largest cross-section and the second point is the point at which the interface has the smallest cross-section. In some embodiments, the in width of the interface does not appreciably or measurably change as a function of length and/or depth of the interface.

In some embodiments, the width of the interface is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the width of the interface is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

The third electrically-conductive component 230 is made of a third material 270 including a gallium-based (Ga-based) alloy 272 and a metallic filler 274, and forms an electrical conduit between the first interface and the second interface. In various embodiments, the metallic filler 274 forms intermetallic compounds with gallium. In some embodiments, the metallic filler 274 also forms intermetallic compounds with other ingredient(s) in the Ga-based alloy 272. In some embodiments, the metallic filler 274 and/or the newly formed intermetallic compounds surround the Ga-based amalgams. As such, the metallic filler 274 reduces a reactivity of the third electrically-conductive component with the first metal at the first and second interfaces so that each of the first and second interfaces is free of deterioration in conductivity for a first period of time, wherein the first period of time is at least 1000 hours.

In some embodiments, the first period of time starts after the first and second interfaces are formed. In some embodiments, the first period of time is at least 1500 hours, at least 2000 hours, at least 2500 hours, at least 3000 hours, at least 3500 hours, at least 4000 hours, at least 4500 hours, at least 5000 hours, at least 5500 hours, at least 6000 hours, at least 6500 hours, at least 7000 hours, at least 7500 hours, or at least 8000 hours. In some embodiments, the first period of time is at least 100 days, at least 150 days, at least 200 days, at least 250 days, or at least 300 days. In some embodiments, the first period of time is at least a year, at least 1.5 years, at least 2 years, at least 2.5 years, at least 3 years, at least 3.5 year, at least 4 years, at least 4.5 years, or at least 5 years.

In some embodiments, an interface (e.g., the first interface 242, the second interface 244) is free of deterioration when a second conductivity of the interface (e.g., the conductivity of the interface during the first period of time) satisfies a threshold ratio in comparison against a first conductivity of the interface (e.g., when it is initially formed, manufactured). In some embodiments, the threshold ratio is between 0.99 and 1.01, between 0.995 and 1.005, or between 0.999 and 1.001. In some embodiments, the threshold ratio is at least 0.9, at least 0.95, at least 1, at least 1.05, or at least 1.1. In some embodiments, the threshold ratio is at most 0.95, at most 0.96, at most 0.97, at most 0.98, at most 0.99, at most 0.999, at most 0.9999, at most 1, at most 1.0001, at most 1.001, at most 1.01, at most 1.02, at most 1.03, at most 1.04, at most 1.05, or at most 1.1.

In some embodiments, the substrate 110 is a deformable substrate. An interface (e.g., the first interface 242, the second interface 244) is free of deterioration in conductivity when the deformable substrate is bent, such as bent around a cylinder. In some embodiments, an interface is free of deterioration in conductivity when the deformable substrate is that has a radius of between 2 centimeters (cm) and 10 cm, between 2 cm and 8 cm, between 2 cm and 6 cm, between 2 cm and 4 cm, 4 cm and 10 cm, between 4 cm and 8 cm, between 4 cm and 6 cm, between 6 cm and 10 cm, between 6 cm and 8 cm, or between 8 cm and 10 cm for a period of time and then released. In some embodiments, the radius of the cylinder is at least 2 cm, at least 3 cm, at least 4 cm, at least 5 cm, at least 6 cm, at least 7 cm, at least 8 cm, at least 9 cm, or at least 10 cm. In some embodiments, the radius of the cylinder is at most 2 cm, at most 3 cm, at most 4 cm, at most 5 cm, at most 6 cm, at most 7 cm, at most 8 cm, at most 9 cm, or at most 10 cm.

In some embodiments, the period of time is between 10 seconds and 5 minutes, between 10 seconds and 4 minutes, between 10 seconds and 3 minutes, between 10 seconds and 2 minutes, between 10 seconds and 1 minute, between 10 seconds and 30 seconds, between 30 seconds and 5 minutes, between 10 seconds and 4 minutes, between 10 seconds and 3 minutes, between 10 seconds and 2 minutes, between 10 seconds and 1 minute, between 1 minute and 5 minutes, between 1 minute and 4 minutes, between 1 minute and 3 minutes, between 1 minute and 2 minutes, or between 3 minutes and 5 minutes. In some embodiments, the period of time is at least 10 seconds, at least 20 seconds, at least 30 seconds, at least 60 seconds, at least 1.5 minutes, at least 2 minutes, at least 2.5 minutes, at least 3 minutes, at least 3.5 minutes, at least 4 minutes, at least 4.5 minutes, or at least 5 minutes. In some embodiments, the period of time is at most 10 seconds, at most 20 seconds, at most 30 seconds, at most 60 seconds, at most 1.5 minutes, at most 2 minutes, at most 2.5 minutes, at most 3 minutes, at most 3.5 minutes, at most 4 minutes, at most 4.5 minutes, or at most 5 minutes.

In some embodiments, the metallic filler 274 reduces the reactivity of the Ga-based alloy 272 with the first metal 252 that would otherwise cause corrosion, embrittlement, degradation, or open circuit of the first electrically-conductive component 210 at the first interface 242 and corrosion, embrittlement, degradation, or open circuit of the second electrically-conductive component 220 at the second interface 244. As a result, it ensures the electrical connection between the third electrically-conductive component 230 with the first electrically-conductive component 210 at the first interface 242 and the electrical connection between the third electrically-conductive component 230 with the second electrically-conductive component 220 at the second interface 244 for a longer period of time. For instance, in some embodiments, the electrical connection between the third electrically-conductive component with the first electrically-conductive component at the first interface and the electrical connection between the third electrically-conductive component with the second electrically-conductive component at the second interface are maintained for at least 2000 hours, at least 2500 hours, at least 3000 hours, at least 3500 hours, at least 4000 hours, at least 4500 hours, at least 5000 hours, at least 5500 hours, at least 6000 hours, at least 6500 hours, at least 7000 hours, at least 7500 hours, or at least 8000 hours.

As used herein, the term “electrical connection” refers to an electrical connection maintained through a portion of the circuit having a resistance below a resistance threshold. In some embodiments, the resistance threshold is between 0.1 Ω/cm and 100 Ω/cm, between 0.1 Ω/cm and 90 Ω/cm, between 0.1 Ω/cm and 700 Ω/cm, between 0.1 Ω/cm and 50 Ω/cm, between 0.1 Ω/cm and 40 Ω/cm, between 0.1 Ω/cm and 30 Ω/cm, between 0.1 Ω/cm and 25 Ω/cm, between 0.1 Ω/cm and 20 Ω/cm, between 0.1 Ω/cm and 10 Ω/cm, between 0.1 Ω/cm and 5 Ω/cm, between 0.1 Ω/cm and 3 Ω/cm, between 0.5 Ω/cm and 100 Ω/cm, between 0.5 Ω/cm and 90 Ω/cm, between 0.5 Ω/cm and 70 Ω/cm, between 0.5 Ω/cm and 50 Ω/cm, between 0.5 Ω/cm and 40 Ω/cm, between 0.5 Ω/cm and 30 Ω/cm, between 0.5 Ω/cm and 25 Ω/cm, between 0.5 Ω/cm and 20 Ω/cm, between 0.5 Ω/cm and 10 Ω/cm, between 0.5 Ω/cm and 5 Ω/cm, between 0.5 Ω/cm and 3 Ω/cm, between 1 Ω/cm and 100 Ω/cm, between 1 Ω/cm and 90 Ω/cm, between 1 Ω/cm and 70 Ω/cm, between 1 Ω/cm and 50 Ω/cm, between 1 Ω/cm and 40 Ω/cm, between 1 Ω/cm and 30 Ω/cm, between 1 Ω/cm and 25 Ω/cm, between 1 Ω/cm and 20 Ω/cm, between 1 Ω/cm and 10 Ω/cm, between 1 Ω/cm and 5 Ω/cm, between 1 Ω/cm and 3 Ω/cm, between 2.5 Ω/cm and 100 Ω/cm, between 2.5 Ω/cm and 90 Ω/cm, between 2.5 Ω/cm and 70 Ω/cm, between 2.5 Ω/cm and 50 Ω/cm, between 2.5 Ω/cm and 40 Ω/cm, between 2.5 Ω/cm and 30 Ω/cm, between 2.5 Ω/cm and 25 Ω/cm, between 2.5 Ω/cm and 20 Ω/cm, between 2.5 Ω/cm and 10 Ω/cm, between 2.5 Ω/cm and 5 Ω/cm, between 2.5 Ω/cm and 3 Ω/cm, between 8 Ω/cm and 100 Ω/cm, between 8 Ω/cm and 90 Ω/cm, between 8 Ω/cm and 70 Ω/cm, between 8 Ω/cm and 50 Ω/cm, between 8 Ω/cm and 40 Ω/cm, between 8 Ω/cm and 30 Ω/cm, between 8 Ω/cm and 25 Ω/cm, between 8 Ω/cm and 20 Ω/cm, between 8 Ω/cm and 10 Ω/cm, between 13 Ω/cm and 100 Ω/cm, between 13 Ω/cm and 90 Ω/cm, between 13 Ω/cm and 70 Ω/cm, between 13 Ω/cm and 50 Ω/cm, between 13 Ω/cm and 40 Ω/cm, between 13 Ω/cm and 30 Ω/cm, between 13 Ω/cm and 25 Ω/cm, between 13 Ω/cm and 20 Ω/cm, between 25 Ω/cm and 100 Ω/cm, between 25 Ω/cm and 90 Ω/cm, between 25 Ω/cm and 70 Ω/cm, between 25 Ω/cm and 50 Ω/cm, between 25 Ω/cm and 40 Ω/cm, between 25 Ω/cm and 30 Ω/cm, between 45 Ω/cm and 100 Ω/cm, between 45 Ω/cm and 90 Ω/cm, between 45 Ω/cm and 70 Ω/cm, between 45 Ω/cm and 50 Ω/cm, between 60 Ω/cm and 100 Ω/cm, between 60 Ω/cm and 90 Ω/cm, between 60 Ω/cm and 70 Ω/cm, between 85 Ω/cm and 100 Ω/cm, or between 85 Ω/cm and 90 Ω/cm.

In some embodiments, the resistance threshold is at least 0.1 Ω/cm, at least 0.4 Ω/cm, at least 0.8 Ω/cm, at least 1 Ω/cm, at least 1.5 Ω/cm, at least 2 Ω/cm, at least 2.5 Ω/cm, at least 3 Ω/cm, at least 3.5 Ω/cm, at least 4 Ω/cm, at least 4.5 Ω/cm, at least 5 Ω/cm, at least 5.5 Ω/cm, at least 6 Ω/cm, at least 6.5 Ω/cm, at least 7 Ω/cm, at least 7.5 Ω/cm, at least 8 Ω/cm, at least 8.5 Ω/cm, at least 9 Ω/cm, at least 9.5 Ω/cm, at least 10 Ω/cm, at least 10.5 Ω/cm, at least 11 Ω/cm, at least 11.5 Ω/cm, at least 12 Ω/cm, at least 12.5 Ω/cm, at least 13 Ω/cm, at least 13.5 Ω/cm, at least 14 Ω/cm, at least 14.5 Ω/cm, at least 15 Ω/cm, at least 15.5 Ω/cm, at least 16 Ω/cm, at least 16.5 Ω/cm, at least 17 Ω/cm, at least 17.5 Ω/cm, at least 18 Ω/cm, at least 18.5 Ω/cm, at least 19 Ω/cm, at least 19.5 Ω/cm, at least 20 Ω/cm, at least 20.5 Ω/cm, at least 21 Ω/cm, at least 21.5 Ω/cm, at least 22 Ω/cm, at least 22.5 Ω/cm, at least 23 Ω/cm, at least 23.5 Ω/cm, at least 24 Ω/cm, at least 24.5 Ω/cm, at least 25 Ω/cm, at least 25.5 Ω/cm, at least 26 Ω/cm, at least 26.5 Ω/cm, at least 27 Ω/cm, at least 27.5 Ω/cm, at least 28 Ω/cm, at least 28.5 Ω/cm, at least 29 Ω/cm, at least 29.5 Ω/cm, at least 30 Ω/cm, at least 30.5 Ω/cm, at least 31 Ω/cm, at least 31.5 Ω/cm, at least 32 Ω/cm, at least 32.5 Ω/cm, at least 33 Ω/cm, at least 33.5 Ω/cm, at least 34 Ω/cm, at least 34.5 Ω/cm, at least 35 Ω/cm, at least 35.5 Ω/cm, at least 36 Ω/cm, at least 36.5 Ω/cm, at least 37 Ω/cm, at least 37.5 Ω/cm, at least 38 Ω/cm, at least 38.5 Ω/cm, at least 39 Ω/cm, at least 39.5 Ω/cm, at least 40 Ω/cm, at least 40.5 Ω/cm, at least 41 Ω/cm, at least 41.5 Ω/cm, at least 42 Ω/cm, at least 42.5 Ω/cm, at least 43 Ω/cm, at least 43.5 Ω/cm, at least 44 Ω/cm, at least 44.5 Ω/cm, at least 45 Ω/cm, at least 45.5 Ω/cm, at least 46 Ω/cm, at least 46.5 Ω/cm, at least 47 Ω/cm, at least 47.5 Ω/cm, at least 48 Ω/cm, at least 48.5 Ω/cm, at least 49 Ω/cm, at least 49.5 Ω/cm, at least 50 Ω/cm, at least 50.5 Ω/cm, at least 51 Ω/cm, at least 51.5 Ω/cm, at least 52 Ω/cm, at least 52.5 Ω/cm, at least 53 Ω/cm, at least 53.5 Ω/cm, at least 54 Ω/cm, at least 54.5 Ω/cm, at least 55 Ω/cm, at least 55.5 Ω/cm, at least 56 Ω/cm, at least 56.5 Ω/cm, at least 57 Ω/cm, at least 57.5 Ω/cm, at least 58 Ω/cm, at least 58.5 Ω/cm, at least 59 Ω/cm, at least 59.5 Ω/cm, at least 60 Ω/cm, at least 60.5 Ω/cm, at least 61 Ω/cm, at least 61.5 Ω/cm, at least 62 Ω/cm, at least 62.5 Ω/cm, at least 63 Ω/cm, at least 63.5 Ω/cm, at least 64 Ω/cm, at least 64.5 Ω/cm, at least 65 Ω/cm, at least 65.5 Ω/cm, at least 66 Ω/cm, at least 66.5 Ω/cm, at least 67 Ω/cm, at least 67.5 Ω/cm, at least 68 Ω/cm, at least 68.5 Ω/cm, at least 69 Ω/cm, at least 69.5 Ω/cm, at least 70 Ω/cm, at least 70.5 Ω/cm, at least 71 Ω/cm, at least 71.5 Ω/cm, at least 72 Ω/cm, at least 72.5 Ω/cm, at least 73 Ω/cm, at least 73.5 Ω/cm, at least 74 Ω/cm, at least 74.5 Ω/cm, at least 75 Ω/cm, at least 75.5 Ω/cm, at least 76 Ω/cm, at least 76.5 Ω/cm, at least 77 Ω/cm, at least 77.5 Ω/cm, at least 78 Ω/cm, at least 78.5 Ω/cm, at least 79 Ω/cm, at least 79.5 Ω/cm, at least 80 Ω/cm, at least 80.5 Ω/cm, at least 81 Ω/cm, at least 81.5 Ω/cm, at least 82 Ω/cm, at least 82.5 Ω/cm, at least 83 Ω/cm, at least 83.5 Ω/cm, at least 84 Ω/cm, at least 84.5 Ω/cm, at least 85 Ω/cm, at least 85.5 Ω/cm, at least 86 Ω/cm, at least 86.5 Ω/cm, at least 87 Ω/cm, at least 87.5 Ω/cm, at least 88 Ω/cm, at least 88.5 Ω/cm, at least 89 Ω/cm, at least 89.5 Ω/cm, at least 90 Ω/cm, at least 90.5 Ω/cm, at least 91 Ω/cm, at least 91.5 Ω/cm, at least 92 Ω/cm, at least 92.5 Ω/cm, at least 93 Ω/cm, at least 93.5 Ω/cm, at least 94 Ω/cm, at least 94.5 Ω/cm, at least 95 Ω/cm, at least 95.5 Ω/cm, at least 96 Ω/cm, at least 96.5 Ω/cm, at least 97 Ω/cm, at least 97.5 Ω/cm, at least 98 Ω/cm, at least 98.5 Ω/cm, at least 99 Ω/cm, at least 99.5 Ω/cm, or at least 100 Ω/cm.

In some embodiments, the resistance threshold is at most 0.1 Ω/cm, at most 0.4 Ω/cm, at most 0.8 Ω/cm, at most 1 Ω/cm, at most 1.5 Ω/cm, at most 2 Ω/cm, at most 2.5 Ω/cm, at most 3 Ω/cm, at most 3.5 Ω/cm, at most 4 Ω/cm, at most 4.5 Ω/cm, at most 5 Ω/cm, at most 5.5 Ω/cm, at most 6 Ω/cm, at most 6.5 Ω/cm, at most 7 Ω/cm, at most 7.5 Ω/cm, at most 8 Ω/cm, at most 8.5 Ω/cm, at most 9 Ω/cm, at most 9.5 Ω/cm, at most 10 Ω/cm, at most 10.5 Ω/cm, at most 11 Ω/cm, at most 11.5 Ω/cm, at most 12 Ω/cm, at most 12.5 Ω/cm, at most 13 Ω/cm, at most 13.5 Ω/cm, at most 14 Ω/cm, at most 14.5 Ω/cm, at most 15 Ω/cm, at most 15.5 Ω/cm, at most 16 Ω/cm, at most 16.5 Ω/cm, at most 17 Ω/cm, at most 17.5 Ω/cm, at most 18 Ω/cm, at most 18.5 Ω/cm, at most 19 Ω/cm, at most 19.5 Ω/cm, at most 20 Ω/cm, at most 20.5 Ω/cm, at most 21 Ω/cm, at most 21.5 Ω/cm, at most 22 Ω/cm, at most 22.5 Ω/cm, at most 23 Ω/cm, at most 23.5 Ω/cm, at most 24 Ω/cm, at most 24.5 Ω/cm, at most 25 Ω/cm, at most 25.5 Ω/cm, at most 26 Ω/cm, at most 26.5 Ω/cm, at most 27 Ω/cm, at most 27.5 Ω/cm, at most 28 Ω/cm, at most 28.5 Ω/cm, at most 29 Ω/cm, at most 29.5 Ω/cm, at most 30 Ω/cm, at most 30.5 Ω/cm, at most 31 Ω/cm, at most 31.5 Ω/cm, at most 32 Ω/cm, at most 32.5 Ω/cm, at most 33 Ω/cm, at most 33.5 Ω/cm, at most 34 Ω/cm, at most 34.5 Ω/cm, at most 35 Ω/cm, at most 35.5 Ω/cm, at most 36 Ω/cm, at most 36.5 Ω/cm, at most 37 Ω/cm, at most 37.5 Ω/cm, at most 38 Ω/cm, at most 38.5 Ω/cm, at most 39 Ω/cm, at most 39.5 Ω/cm, at most 40 Ω/cm, at most 40.5 Ω/cm, at most 41 Ω/cm, at most 41.5 Ω/cm, at most 42 Ω/cm, at most 42.5 Ω/cm, at most 43 Ω/cm, at most 43.5 Ω/cm, at most 44 Ω/cm, at most 44.5 Ω/cm, at most 45 Ω/cm, at most 45.5 Ω/cm, at most 46 Ω/cm, at most 46.5 Ω/cm, at most 47 Ω/cm, at most 47.5 Ω/cm, at most 48 Ω/cm, at most 48.5 Ω/cm, at most 49 Ω/cm, at most 49.5 Ω/cm, at most 50 Ω/cm, at most 50.5 Ω/cm, at most 51 Ω/cm, at most 51.5 Ω/cm, at most 52 Ω/cm, at most 52.5 Ω/cm, at most 53 Ω/cm, at most 53.5 Ω/cm, at most 54 Ω/cm, at most 54.5 Ω/cm, at most 55 Ω/cm, at most 55.5 Ω/cm, at most 56 Ω/cm, at most 56.5 Ω/cm, at most 57 Ω/cm, at most 57.5 Ω/cm, at most 58 Ω/cm, at most 58.5 Ω/cm, at most 59 Ω/cm, at most 59.5 Ω/cm, at most 60 Ω/cm, at most 60.5 Ω/cm, at most 61 Ω/cm, at most 61.5 Ω/cm, at most 62 Ω/cm, at most 62.5 Ω/cm, at most 63 Ω/cm, at most 63.5 Ω/cm, at most 64 Ω/cm, at most 64.5 Ω/cm, at most 65 Ω/cm, at most 65.5 Ω/cm, at most 66 Ω/cm, at most 66.5 Ω/cm, at most 67 Ω/cm, at most 67.5 Ω/cm, at most 68 Ω/cm, at most 68.5 Ω/cm, at most 69 Ω/cm, at most 69.5 Ω/cm, at most 70 Ω/cm, at most 70.5 Ω/cm, at most 71 Ω/cm, at most 71.5 Ω/cm, at most 72 Ω/cm, at most 72.5 Ω/cm, at most 73 Ω/cm, at most 73.5 Ω/cm, at most 74 Ω/cm, at most 74.5 Ω/cm, at most 75 Ω/cm, at most 75.5 Ω/cm, at most 76 Ω/cm, at most 76.5 Ω/cm, at most 77 Ω/cm, at most 77.5 Ω/cm, at most 78 Ω/cm, at most 78.5 Ω/cm, at most 79 Ω/cm, at most 79.5 Ω/cm, at most 80 Ω/cm, at most 80.5 Ω/cm, at most 81 Ω/cm, at most 81.5 Ω/cm, at most 82 Ω/cm, at most 82.5 Ω/cm, at most 83 Ω/cm, at most 83.5 Ω/cm, at most 84 Ω/cm, at most 84.5 Ω/cm, at most 85 Ω/cm, at most 85.5 Ω/cm, at most 86 Ω/cm, at most 86.5 Ω/cm, at most 87 Ω/cm, at most 87.5 Ω/cm, at most 88 Ω/cm, at most 88.5 Ω/cm, at most 89 Ω/cm, at most 89.5 Ω/cm, at most 90 Ω/cm, at most 90.5 Ω/cm, at most 91 Ω/cm, at most 91.5 Ω/cm, at most 92 Ω/cm, at most 92.5 Ω/cm, at most 93 Ω/cm, at most 93.5 Ω/cm, at most 94 Ω/cm, at most 94.5 Ω/cm, at most 95 Ω/cm, at most 95.5 Ω/cm, at most 96 Ω/cm, at most 96.5 Ω/cm, at most 97 Ω/cm, at most 97.5 Ω/cm, at most 98 Ω/cm, at most 98.5 Ω/cm, at most 99 Ω/cm, at most 99.5 Ω/cm, or at most 100 Ω/cm.

In some embodiments, the Ga-based alloy 272 includes a Ga-based liquid metal alloy. In certain embodiments, the Ga-based liquid metal alloy is a gallium indium alloy (e.g., eutectic GaIn), a gallium tin alloy, a gallium indium tin alloy (e.g., Galinstan), a gallium indium tin zinc alloy, or any combination thereof. In some embodiments, the gallium in the Ga-based liquid metal alloy is between about 75 and 95 percent by weight, between about 50 and 75 percent by weight, between about 25 and 50 percent by weight, or less than about 25 percent by weight of the Ga-based liquid metal alloy. In an embodiments, the Ga-based liquid metal alloy includes Ga75.5In24.5, Ga67In20.5Sn12.5, Ga61In25Sn13Zn1, or any combination thereof. Ga75.5In24.5 has a melting point of about 15.5° C., Ga67In20.5Sn12.5 has a melting point of about 10.5° C., and Ga61In25Sn13Zn1 has a melting point of about 7.6° C.

The metallic filler 274 is typically in the form of microflakes, nanoflakes, microparticles, nanoparticles, nanowires, nanotubes, or a combination thereof. In some embodiments, the particles of the metallic filler 274 in the composition have a dimension of about 10 μm to 5 μm, about 5 μm to 1 μm, or less than 1 μm. Any suitable metal can be used as the metallic filler 274, including but not limited to aluminum, titanium, cobalt, nickel, copper, zinc, silver, gold, indium, tin, or tungsten. In some embodiments, the metallic filler 274 includes silver, copper, gold, or a mixture thereof. In some embodiments, the metallic filler 274 includes a metal alloy, such as nitinols (nickel-titanium alloys) or the like.

The metallic filler 274 can, but does not necessarily have to, include the first metal 252 contained in the first material 250 and the second material 260. For instance, in some embodiments, the first metal 252 is silver, and the metallic filler 274 includes the first metal 252, i.e., silver, in the form of microflakes, nanoflakes, microparticles, nanoparticles, nanowires, nanotubes, or a combination thereof and mixed with the Ga-based alloy 272. In some alternative embodiments, the metallic filler 274 does not include the first metal 252, i.e., silver; instead, it includes a metal other than silver, such as aluminum, titanium, cobalt, nickel, copper, zinc, gold, indium, tin, nitinol, or tungsten, or a mixture thereof, in the form of microflakes, nanoflakes, microparticles, nanoparticles, nanowires, nanotubes, or a combination thereof and mixed with the Ga-based alloy 272. Similarly, in some embodiments, the first metal 252 is copper, and the metallic filler 274 includes the first metal 252, i.e., copper, in the form of microflakes, nanoflakes, microparticles, nanoparticles, nanowires, nanotubes, or a combination thereof and mixed with the Ga-based alloy 272. In some alternative embodiments, the metallic filler 274 does not include the first metal 252, i.e., copper; instead, it includes a metal other than copper, such as aluminum, titanium, cobalt, nickel, silver, zinc, gold, indium, tin, nitinol, or tungsten, or a mixture thereof in the form of microflakes, nanoflakes, microparticles, nanoparticles, nanowires, nanotubes, or a combination thereof and mixed with the Ga-based alloy 272.

The third material 270 used for making the third electrically-conductive component can have any suitable amount of the metallic filler 274. For instance, in some embodiments, the third material 270 includes the metallic filler 274 at an amount from about 10% to about 20%, from about 20% to 30%, from about 30% to about 40%, or from about 40% to about 50% by weight of the Ga-based alloy 272.

The third material 270 used for making the third electrically-conductive component can include other additional or optional ingredients. For instance, in some embodiments, the third material 270 used for making the third electrically-conductive component includes a polymeric binder, a solvent, or both. In certain embodiments, the third material 270 used for making the third electrically-conductive component is a solvent-based liquid metal composition. In some embodiments, a solvent-based liquid metal composition includes the Ga-based alloy 272 and metallic filler 274 mixed with a solution that includes at least one solvent and a polymeric binder dissolved in the at least one solvent. Non-limiting examples of a solvent include, but are not limited to toluene, tetrahydrofuran (THF), cycolohexane, xylene, decane, octyle acelate, or 2,2,4-Trimethyl-1,3-pentanediol diisobutyrate (TXIB). Non-limiting examples of the polymeric binder include, but are not limited to, thermoplastic polymer, cellulose, poly(vinyl alcohol), poly(acrylic acid), polyvinylidene fluoride, polyvinyl acetate-polyvinylpyrrolidone, poly(ethylene glycol), amines, silicones, styrene isoprene styrene (SIS), styrene ethylene butylene styrene (SEBS), or any combination thereof.

The solution of a solvent-based liquid metal composition can be tailored with appropriate solvent(s) and polymer(s) to achieve desired properties, such as extended decap time or optimal viscosity. Non-limiting examples include, but are not limited to, a solution of any one or more polymers (e.g., SIS, SEBS, silicone, or the like) dissolved in TXIB, a solution of any one or more polymers dissolved in a solvent mixture including TXIB, a solution of SEBS dissolved in any solvent or solvent mixture, or a solution of a polymer mixture including SEBS dissolved in any solvent or solvent mixture.

A solvent-based liquid metal composition can have any suitable amount of the Ga-based alloy 272. For instance, in some embodiments, a solvent-based liquid metal composition includes the Ga-based alloy 272 at an amount from about 50% to about 60%, from about 60% to about 70%, from about 70% to about 80%, or from about 80% to about 90% by weight of the solvent-based liquid metal composition. In certain embodiments, the Ga-based alloy 272 includes gallium indium alloy, gallium tin alloy, gallium indium tin alloy, or gallium indium tin zinc alloy, or any combination thereof. In some embodiments, the Ga-based alloy 272 includes gallium at an amount of from about 50 wt % to about 55 wt %, from about 55 wt % to about 60 wt %, from about 60 wt % to about 65 wt %, from about 65 wt % to about 70 wt %, from about 70 wt % to about 80 wt %, or from about 80 wt % to about 85 wt % with respect to the weight of the Ga-based alloy 272.

By way of example, Table-I below lists some exemplary solvent-based liquid metal compositions that can be used to make a third electrically-conductive component 230 of the present disclosure.

TABLE I
Exemplary Solvent-based Liquid Metal Compositions

| | EGaIn | Ag | Binder | Solvent | Ag/LM | |
|---|---|---|---|---|---|---|
| Examples | (wt %) | (wt %) | (wt %) | (wt %) | (wt %)¹ | Solution |
| Composition-I | 59.7% | 21.8% | 2.8% | 15.7% | 36.6% | 15% SIS in Toluene |
| Composition-II | 59.7% | 21.8% | 2.8% | 15.7% | 36.6% | 15% SIS in TXIB |
| Composition-III | 59.9% | 21.5% | 2.8% | 15.7% | 35.9% | 15 wt % SIS dissolved |
| | | | | | | in TXIB:Tolune 5% v/v |
| Composition-IV | 53.7% | 22.1% | 1.9% | 22.2% | 41.3% | 8 wt % SEBS dissolved |
| | | | | | | in Toluene |

¹This column is AG (wt %) divided by EGaln (wt %)

In some embodiments, the solvent-based liquid metal composition is tuned to have a large range of decap times. For instance, in some embodiments, the solvent-based liquid metal composition has a decap time of at least 1 minute, at least 2 minutes, at least 5 minutes, at least 15 minutes, at least 20 minutes, or greater than 20 minutes. In some embodiments, a composition of the present disclosure has a decap time of at least half an hour, at least 1 hour, at least 2 hours, at least 3 hours, at least 4 hours, at least 5 hours, or greater than 5 hours.

In some embodiments, the solvent-based liquid metal composition is tuned to have a suitable viscosity to suit different applications. For instance, in some embodiments, at a temperature between 64 degrees Fahrenheit (° F.) and 72° F., a solvent-based liquid metal composition has a viscosity between 0.5 Pascal seconds (Pa·s) and 3 Pa·s, between 0.5 Pa·s and 2.7 Pa·s, between 0.5 Pa·s and 2.5 Pa·s, between 0.5 Pa·s and 2.2 Pa·s, between 0.5 Pa·s and 2 Pa·s, between 0.5 Pa·s and 1.7 Pa·s, between 0.5 Pa·s and 1.5 Pa·s, between 0.5 Pa·s and 1.2 Pa·s, between 0.5 Pa·s and 1 Pa·s, between 0.5 Pa·s and 0.7 Pa·s, between 1 Pa·s and 3 Pa·s, between 1 Pa·s and 2.7 Pa·s, between 1 Pa·s and 2.5 Pa·s, between 1 Pa·s and 2.2 Pa·s, between 1 Pa·s and 2 Pa·s, between 1 Pa·s and 1.7 Pa·s, between 1 Pa·s and 1.5 Pa·s, between 1 Pa·s and 1.2 Pa·s, between 1.5 Pa·s and 3 Pa·s, between 1.5 Pa·s and 2.7 Pa·s, between 1.5 Pa·s and 2.5 Pa·s, between 1.5 Pa·s and 2.2 Pa·s, between 1.5 Pa·s and 2 Pa·s, between 1.5 Pa·s and 1.7 Pa·s, between 2 Pa·s and 3 Pa·s, between 2 Pa·s and 2.7 Pa·s, between 2 Pa·s and 2.5 Pa·s, between 2 Pa·s and 2.2 Pa·s, between 2.5 Pa·s and 3 Pa·s, or between 2.5 Pa·s and 2.7 Pa·s.

In some embodiments, at a temperature between 64° F. and 72° F., a solvent-based liquid metal composition has a viscosity of at least 0.5 Pa·s, at least 0.7 Pa·s, at least 0.9 Pa·s, at least 1 Pa·s, at least 1.1 Pa·s, at least 1.3 Pa·s, at least 1.5 Pa·s, at least 1.7 Pa·s, at least 1.9 Pa·s, at least 2 Pa·s, at least 2.1 Pa·s, at least 2.3 Pa·s, at least 2.5 Pa·s, at least 2.7 Pa·s, at least 2.9 Pa·s, or at least 3 Pa·s. In some embodiments, a composition of the present disclosure, at a temperature between 64° F. and 72° F., has a viscosity of at most 0.5 Pa·s, at most 0.7 Pa·s, at most 0.9 Pa·s, at most 1 Pa·s, at most 1.1 Pa·s, at most 1.3 Pa·s, at most 1.5 Pa·s, at most 1.7 Pa·s, at most 1.9 Pa·s, at most 2 Pa·s, at most 2.1 Pa·s, at most 2.3 Pa·s, at most 2.5 Pa·s, at most 2.7 Pa·s, at most 2.9 Pa·s, or at most 3 Pa·s.

In some embodiments, at a temperature between 18 degrees Celcius (° C.) and 22° C., a solvent-based liquid metal composition has a viscosity between 500 centipoise (cps) and 3,000 cps, between 500 cps and 2,750 cps, between 500 cps and 2,500 cps, between 500 cps and 2,250 cps, between 500 cps and 2,000 cps, between 500 cps and 1,750 cps, between 500 cps and 1,500 cps, between 500 cps and 1,250 cps, between 500 cps and 1,000 cps, between 500 cps and 750 cps, between 700 cps and 3,000 cps, between 700 cps and 2,750 cps, between 700 cps and 2,500 cps, between 700 cps and 2,250 cps, between 700 cps and 2,000 cps, between 700 cps and 1,750 cps, between 700 cps and 1,500 cps, between 700 cps and 1,250 cps, between 700 cps and 1,000 cps, between 700 cps and 750 cps, between 900 cps and 3,000 cps, between 900 cps and 2,750 cps, between 900 cps and 2,500 cps, between 900 cps and 2,250 cps, between 900 cps and 2,000 cps, between 900 cps and 1,750 cps, between 900 cps and 1,500 cps, between 900 cps and 1,250 cps, between 900 cps and 1,000 cps, between 1,100 cps and 3,000 cps, between 1,100 cps and 2,750 cps, between 1,100 cps and 2,500 cps, between 1,100 cps and 2,250 cps, between 1,100 cps and 2,000 cps, between 1,100 cps and 1,750 cps, between 1,100 cps and 1,500 cps, between 1,100 cps and 1,250 cps, between 1,300 cps and 3,000 cps, between 1,300 cps and 2,750 cps, between 1,300 cps and 2,500 cps, between 1,300 cps and 2,250 cps, between 1,300 cps and 2,000 cps, between 1,300 cps and 1,750 cps, between 1,300 cps and 1,500 cps, between 1,500 cps and 3,000 cps, between 1,500 cps and 2,750 cps, between 1,500 cps and 2,500 cps, between 1,500 cps and 2,250 cps, between 1,500 cps and 2,000 cps, between 1,500 cps and 1,750 cps, between 1,700 cps and 3,000 cps, between 1,700 cps and 2,750 cps, between 1,700 cps and 2,500 cps, between 1,700 cps and 2,250 cps, between 1,700 cps and 2,000 cps, between 1,700 cps and 1,750 cps, between 1,700 cps and 1,500 cps, between 1,700 cps and 1,250 cps, between 1,700 cps and 1,000 cps, between 1,900 cps and 3,000 cps, between 1,900 cps and 2,750 cps, between 1,900 cps and 2,500 cps, between 1,900 cps and 2,250 cps, between 1,900 cps and 2,000 cps, between 2,100 cps and 3,000 cps, between 2,100 cps and 2,750 cps, between 2,100 cps and 2,500 cps, between 2,100 cps and 2,250 cps, between 2,300 cps and 3,000 cps, between 2,300 cps and 2,750 cps, between 2,300 cps and 2,500 cps, between 2,500 cps and 3,000 cps, between 2,500 cps and 2,750 cps, between 2,700 cps and 3,000 cps, between 2,700 cps and 2,750 cps, or between 2,900 cps and 3,000 cps.

In some embodiments, at a temperature between 18° C. and 22° C., a solvent-based liquid metal composition has a viscosity of at least 500 cps, at least 600 cps, at least 700 cps, at least 800 cps, at least 900 cps, at least 1,000 cps, at least 1,100 cps, at least 1,200 cps, at least 1,300 cps, at least 1,400 cps, at least 1,500 cps, at least 1,600 cps, at least 1,700 cps, at least 1,800 cps, at least 1,900 cps, at least 2,000 cps, at least 2,100 cps, at least 2,200 cps, at least 2,300 cps, at least 2,400 cps, at least 2,500 cps, at least 2,600 cps, at least 2,700 cps, at least 2,800 cps, at least 2,900 cps, or at least 3,000 cps. In some embodiments, a composition of the present disclosure, at a temperature between 18° C. and 22° C., has a viscosity of at most 500 cps, at most 600 cps, at most 700 cps, at most 800 cps, at most 900 cps, at most 1,000 cps, at most 1,100 cps, at most 1,200 cps, at most 1,300 cps, at most 1,400 cps, at most 1,500 cps, at most 1,600 cps, at most 1,700 cps, at most 1,800 cps, at most 1,900 cps, at most 2,000 cps, at most 2,100 cps, at most 2,200 cps, at most 2,300 cps, at most 2,400 cps, at most 2,500 cps, at most 2,600 cps, at most 2,700 cps, at most 2,800 cps, at most 2,900 cps, or at most 3,000 cps.

In some embodiments, a solvent-based liquid metal composition is tuned to achieve a higher electrical conductivity (e.g., a conductivity measured after the composition is printed on a substrate and dried). For instance, in some embodiments, a composition of the present disclosure has a measured conductivity of greater than about 3×10⁵ S/m (siemens per meter), greater than about 4×10⁵ S/m, greater than about 5×10⁵ S/m, greater than about 6×10⁵ S/m, greater than 7×10⁵ S/m, greater than 8×10⁵ S/m, greater than 9×10⁵ S/m, greater than 1×10⁶ S/m, greater than 1.1×10⁶ S/m, or greater than 1.2×10⁶ S/m.

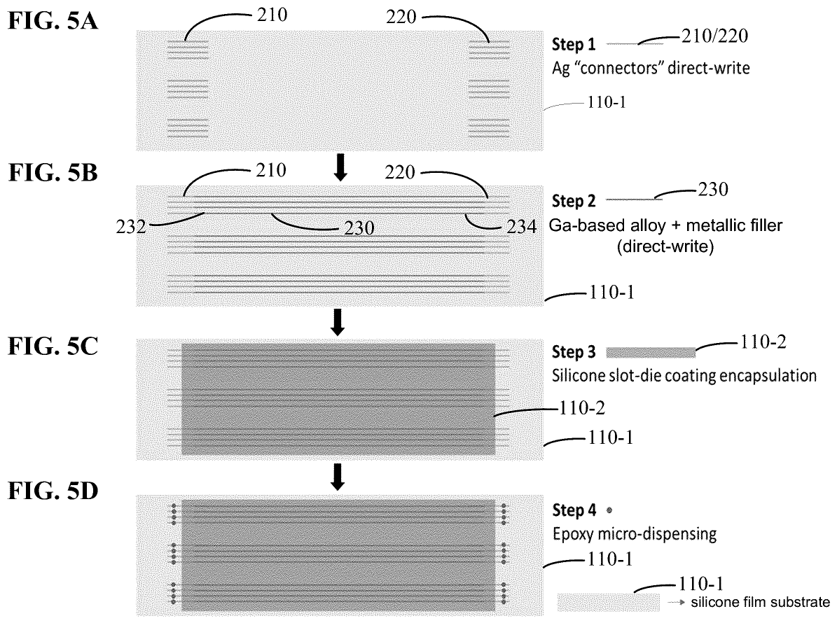

In some embodiments, the substrate 110 includes one or more layers, and the first, second and third electrically-conductive components are in a common layer of the substrate 110. For instance, by way of example, FIG. 5A illustrates a first set of first electrically-conductive components 210 and a second set of second electrically-conductive components 220 formed on a common layer, e.g., a first layer 110-1, of the substrate. The first set of first electrically-conductive components 210 is made of a first material 250 including the first metal 252 (e.g., Ag). The second set of second electrically-conductive components 220 is made of a second material 260 including the first metal 252 (e.g., Ag). FIG. 5B illustrates a third set of third electrically-conductive components 230 formed on the first layer 110-1 of the substrate. The third set of third electrically-conductive components 230 is made of a third material 270 including a Ga-based alloy 272 and a metallic filler 274. As shown, a third electrically-conductive component 230 has a first end portion 232 and a second end portion 234. The first end portion 232 of the third electrically-conductive component 230 overlays a portion of a first electrically-conductive component 210 and thus forms a first interface in between. The second end portion 234 of the third electrically-conductive component 230 overlays a portion of a second electrically-conductive component 220 and thus forms a second interface in between. In some embodiments, each third electrically-conductive component in the third set of third electrically-conductive components is a line.

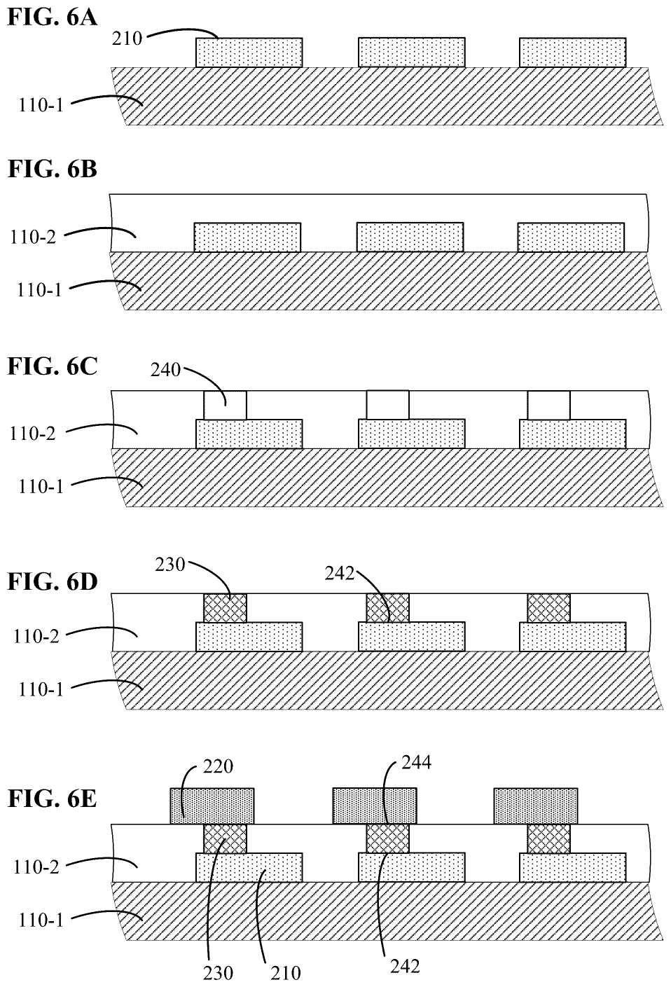

In some embodiments, the substrate 110 includes a plurality of layers with the first and second electrically-conductive components in different layers of the substrate. For instance, by way of example, FIG. 6E illustrates the substrate including at least a layer 110-1 and a layer 110-2. A first set of first electrically-conductive components 210 is formed on the first layer 110-1, and a second set of second electrically-conductive components 220 is formed on the second layer 110-2. The first set of first electrically-conductive components 210 is made of a first material 250 including the first metal 252 (e.g., Ag, Au, Ti, NiTi, W, or Cu). The second set of second electrically-conductive components 220 is made of a second material 260 including the first metal 252 (e.g., Ag, Au, Ti, NiTi, W, or Cu). A third set of third electrically-conductive components 230 is formed between the first and second third electrically-conductive components. The third set of third electrically-conductive components 230 is made of a third material 270 a Ga-based alloy 272 and a metallic filler 274. As shown, a third electrically-conductive component 230 has a first end portion forming a first interface 242 with a first electrically-conductive component 210 and a second end portion forming a second interface 244 with a second electrically-conductive component 220. In some embodiments, each third electrically-conductive component in the third set of third electrically-conductive components is a via. While FIG. 6E illustrates that the second layer 110-2 is adjacent to the first layer 110-1, it should be noted that the present disclosure is not limited thereof. For instance, in some embodiments, a first electrically-conductive component is in a first layer and a second electrically-conductive component is in a second layer that is separated from the first layer by one, two, three, four, five or more than five layers.

Since the third electrically-conductive component 230 is made of the third material 270 including the Ga-based alloy 272 and the metallic filler 274, the reactivity of the third electrically-conductive component with the first metal 252 at the first and second interfaces is reduced. This reduces the deterioration (e.g., corrosion, degradation, embrittlement) of the first electrically-conductive component 210 at the first interface 242 and deterioration of the second electrically-conductive component 220 at the second interface 244, and thus improves the integrity and stability of the circuit.

In some embodiments, the first set of first electrically-conductive components 210 consists of a single first electrically-conductive component. Alternatively, in some embodiments, the first set of first electrically-conductive components 210 includes at least 2, at least 3, at least 4, at least 5, at least 10, at least 20, at least 30, at least 40, or at least 50 first electrically-conductive components. Similarly, in some embodiments, the second set of second electrically-conductive components 220 consists of a single second electrically-conductive component. Alternatively, in some embodiments, the second set of second electrically-conductive components 220 includes at least 2, at least 3, at least 4, at least 5, at least 10, at least 20, at least 30, at least 40, or at least 50 second electrically-conductive components. In some embodiments, the third set of third electrically-conductive components 220 consists of a single third electrically-conductive component. Alternatively, in some embodiments, the third set of third electrically-conductive components 220 includes at least 2, at least 3, at least 4, at least 5, at least 10, at least 20, at least 30, at least 40, or at least 50 third electrically-conductive components.

In some embodiments where the third set of third electrically-conductive components includes a plurality of traces, adjacent traces are separated by a distance greater than a distance threshold. In some embodiments, adjacent traces are separated by a distance of at least about 20 μm, at least about 40 μm, at least about 60 μm, at least about 80 μm, at least about 100 μm, at least about 120 μm, at least about 140 μm, at least about 160 μm, at least about 180 μm, or at least about 200 μm.

In some embodiments, the first circuit 200 includes a plurality of first electrically-conductive components made of a first material 250 including a first metal 252, a plurality of second electrically-conductive components made of a second material 260 including the first metal 252, and a plurality of third electrically-conductive components made of a third material 270 including a Ga-based alloy 272 and a metallic filler 274. Moreover, at least one first electrically-conductive component in the plurality of first electrically-conductive components is in a common layer with at least one second electrically-conductive component in the plurality of second electrically-conductive components and in a different layer with at least another second electrically-conductive component in the plurality of second electrically-conductive components. Further, the plurality of third electrically-conductive components includes at least one trace and at least one via.

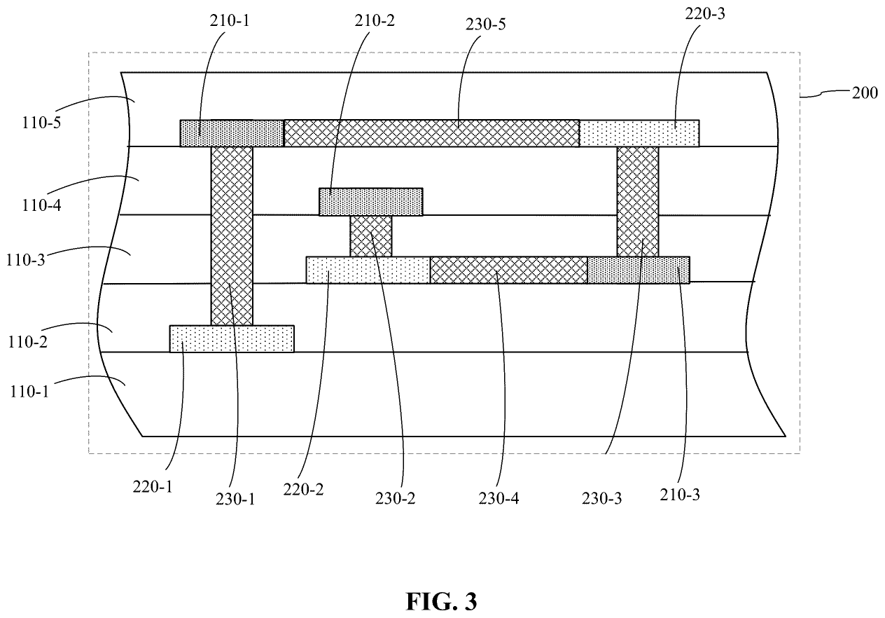

For instance, by way of example, FIG. 3 illustrates the first circuit 200 includes a plurality of first electrically-conductive components 210-1, 210-2 and 210-3, and a plurality of second electrically-conductive components 220-1, 220-2 and 220-3. The second electrically-conductive component 220-1 is in a layer 110-2. The first electrically-conductive component 210-3 and the second electrically-conductive component 220-3 are in a layer 110-3. The first electrically-conductive component 210-2 is in a layer 110-4. The first electrically-conductive component 210-1 and the second electrically-conductive component 230-3 are in a layer 110-5.

The first circuit 200 also includes a plurality of third electrically-conductive components 230-1, 230-2, 230-3, 230-4 and 230-5. The third electrically-conductive component 230-1 is a via, and electrically connects the first electrically-conductive component 210-1 and the second electrically-conductive component 220-1 that are in two different layers. Similarly, the third electrically-conductive component 230-2 is a via, and electrically connects the first electrically-conductive component 210-2 and the second electrically-conductive component 220-2 that are in two different layers. The third electrically-conductive component 230-3 is a via, and electrically connects the first electrically-conductive component 210-3 and the second electrically-conductive component 220-3 that are in two different layers. The third electrically-conductive component 230-4 is a trace or a plurality of traces, and electrically connects the first electrically-conductive component 210-3 and the second electrically-conductive component 220-2 that are in the common layer 110-3. Similarly, the third electrically-conductive component 230-5 is a trace or a plurality of traces, and electrically connects the first electrically-conductive component 210-1 and the second electrically-conductive component 220-3 that are in the common layer 110-5.

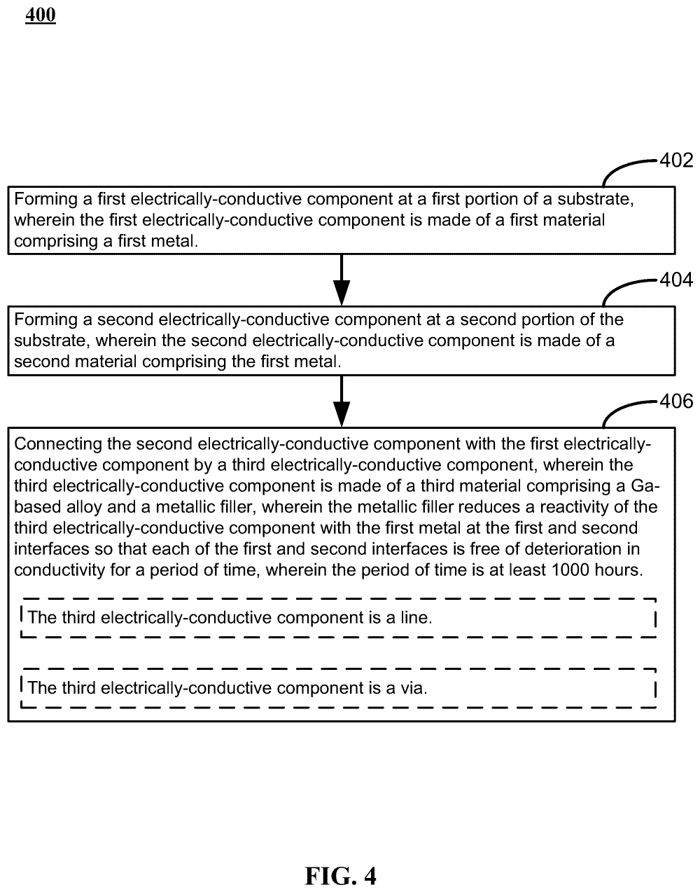

Referring now to FIG. 4, there is depicted a flow chart illustrating an exemplary method 400 for manufacturing an electronic device such as the electronic device 100. The method 400 includes forming a first electrically-conductive component at a first portion of a substrate (block 402), and forming a second electrically-conductive component at a second portion of the substrate (block 404). The first electrically-conductive component is made of a first material 250 including a first metal 252 (e.g., Ag, Au, Cu, Ti, NiTi, or W). The second electrically-conductive component is made of a second material 260 including the first metal 252 (e.g., Ag, Au, Cu, Ti, NiTi, or W). As disclosed elsewhere herein, while both the first and second materials include the first metal 252, the first and second materials can be the same or different.

The method 400 also includes connecting the second electrically-conductive component with the first electrically-conductive component by a third electrically-conductive component (block 406). The third electrically-conductive component is made of a third material 270 including a Ga-based alloy 272 and a metallic filler 274. The metallic filler 274 is selected such that it reduces a reactivity of the Ga-based alloy 272 with the first metal 252, and thus minimizes deterioration of the first and second electrically-conductive components at the interfaces over time. For instance, in some embodiments, the metallic filler reduces a reactivity of the third electrically-conductive component with the first metal at the first and second interfaces so that each of the first and second interfaces is free of deterioration in conductivity for a period of time (e.g., at least 1000 hours, at least 1500 hours, at least 2000 hours, at least 2500 hours, at least 3000 hours, at least 3500 hours, at least 4000 hours, at least 4500 hours, at least 5000 hours, at least 5500 hours, at least 6000 hours, at least 6500 hours, at least 7000 hours, at least 7500 hours, at least 8000 hours, at least 100 days, at least 150 days, at least 200 days, at least 250 days, at least 300 days, at least a year, at least 1.5 years, at least 2 years, at least 2.5 years, at least 3 years, at least 3.5 year, at least 4 years, at least 4.5 years, or at least 5 years).

Referring to FIGS. 5A-5D, in some embodiments, the third electrically-conductive component is a line. For instance, to form a line that couples the first electrically-conductive component and second electrically-conductive component, in some embodiments, the method forms the first and second electrically-conductive components on a common layer of the substrate. As a non-limiting example, FIG. 5A illustrates that the method forms a first set of first electrically-conductive components 210 and a second set of second electrically-conductive components 220 on a common layer, e.g., a first layer 110-1, of the substrate 110. In particular, the first set of first electrically-conductive components 210 is formed on a first portion of the common layer of the substrate 110, and the second set of second electrically-conductive components 220 is formed on a second portion of the common layer of the substrate 110. In some embodiments, each of the first and second electrically-conductive components is made of a material including the first metal 252 (e.g., Cu, Au, Ag, Ti, NiTi, W, or a combination thereof).

The method then forms a third set of third electrically-conductive components 230, as illustrated in FIG. 5B, to couple the first set of first electrically-conductive components and the second set of second electrically-conductive components. As shown, a third electrically-conductive component 230 has a first end portion 232 and a second end portion 234. The first end portion 232 of the third electrically-conductive component 230 overlays a portion of a first electrically-conductive component 210 and thus forms a first interface in between. The second end portion 234 of the third electrically-conductive component 230 overlays a portion of a second electrically-conductive component 220 and thus forms a second interface in between.

In some embodiments, a second layer 110-2 is applied to encapsulate at least a portion of the first layer 110-1, for instance, using a slot-die coating technique, as illustrated in FIG. 5C. In some embodiments, the second layer 110-2 is made of a material including Si. In some embodiments, epoxy micro-dispensing is performed as illustrated in FIG. 5D.

Referring to FIGS. 6A-6E, in some embodiments, the third electrically-conductive component is a via. To form a via that couples the first electrically-conductive component and second electrically-conductive component, in some embodiments, the method forms the first and second electrically-conductive components on two different layers (one layer being a first portion and the other being a second portion) of the substrate 110. As a non-limiting example, in some embodiments, the method forms a first set of first electrically-conductive components 210 on a first layer 110-1 of the substrate 110, as illustrated in FIG. 6A. The first electrically-conductive component is made of a first material 250 including a first metal 252 (e.g., Ag, Au, Cu, Ti, NiTi, or W).

The method then overlays a second layer 110-2 on the first layer 110-1, for instance, using a slot-die coating technique, as illustrated in FIG. 6B. The second layer 110-2 encapsulates at least a portion of the first set of first electrically-conductive components 210. The method then creates a set of channels 240, for instance, using a laser or the like, through the second layer 110-2, as illustrated in FIG. 6C. In some embodiments, each channel is extended to a first electrically-conductive component in the first set of the first electrically-conductive components. The set of channels is filled, for instance, using extrusion-based additive manufacturing method such as direct printing techniques, with a third material 270 (i.e., a material including a Ga-based alloy 272 and a metallic filler 274), to form a third set of third electrically-conductive components 230, as illustrated in FIG. 6D. In some embodiments, each third electrically-conductive component 230 is a via. A third electrically-conductive component 230 has a first end portion forming a first interface 242 with the first electrically-conductive component 210.

After that, the method forms a second set of second electrically-conductive components 220 on the second layer 110-2, as illustrated in FIG. 6E. The second set of second electrically-conductive components 220 is made of a second material 260 including the first metal 252 (e.g., Ag, Au, Cu, Ti, NiTi, or W). A third electrically-conductive component 230 has a second end portion forming a second interface 244 with the second electrically-conductive component 220. In some embodiments, each second circuit in the second set of second electrically-conductive components 220 contacts a third electrically-conductive component in the third set of third electrically-conductive components 230.

The third electrically-conductive component 230 is made of a third material 270 disclosed herein, i.e., a material including a Ga-based alloy 272 and a metallic filler 274, and/or other optional/additional ingredient(s) such as a polymeric binder, solvent(s) or the like. In various embodiments, the metallic filler 274 forms intermetallic compounds with gallium and/or with other ingredient(s) in the Ga-based alloy 272. In some embodiments, the metallic filler 274 and/or the newly formed intermetallic compounds surround the Ga-based amalgams. As such, the metallic filler 274 reduces a reactivity of the third electrically-conductive component at the first and second interfaces, and thus minimizes deterioration of the first electrically-conductive component and the second electrically-conductive component over time. For instance, in some embodiments, the metallic filler reduces a reactivity of the third electrically-conductive component with the first metal at the first and second interfaces so that each of the first and second interfaces is free of deterioration in conductivity for a period of time (e.g., at least 1000 hours, at least 1500 hours, at least 2000 hours, at least 2500 hours, at least 3000 hours, at least 3500 hours, at least 4000 hours, at least 4500 hours, at least 5000 hours, at least 5500 hours, at least 6000 hours, at least 6500 hours, at least 7000 hours, at least 7500 hours, at least 8000 hours, at least 100 days, at least 150 days, at least 200 days, at least 250 days, at least 300 days, at least a year, at least 1.5 years, at least 2 years, at least 2.5 years, at least 3 years, at least 3.5 year, at least 4 years, at least 4.5 years, or at least 5 years). In some embodiments, the third set of third electrically-conductive components 230 is formed by an extrusion-based additive manufacturing method such as direct printing techniques.

In some embodiments, the first set of first electrically-conductive components 210 consists of a single first electrically-conductive component. Alternatively, in some embodiments, the first set of first electrically-conductive components 210 includes at least 2, at least 3, at least 4, at least 5, at least 10, at least 20, at least 30, at least 40, or at least 50 first electrically-conductive components. Similarly, in some embodiments, the second set of second electrically-conductive components 220 consists of a single second electrically-conductive component. Alternatively, in some embodiments, the second set of second electrically-conductive components 220 includes at least 2, at least 3, at least 4, at least 5, at least 10, at least 20, at least 30, at least 40, or at least 50 second electrically-conductive components. In some embodiments, the third set of third electrically-conductive components 220 consists of a single third electrically-conductive component. Alternatively, in some embodiments, the third set of third electrically-conductive components 220 includes at least 2, at least 3, at least 4, at least 5, at least 10, at least 20, at least 30, at least 40, or at least 50 third electrically-conductive components.

The line or via can be formed using, for instance, an extrusion-based additive manufacturing method such as direct printing techniques. In some embodiments, the third material 270 includes a polymeric binder, or is a solvent-based liquid metal composition disclosed herein. In such embodiments, subsequent to the forming of the third electrically-conductive component, the polymeric binder or at least a portion of it polymerizes thereby forming the line or via that couples, and electrically connects, the first electrically-conductive component and second electrically-conductive component. For instance, in some embodiments, to obtain higher conductivity, after the forming, the circuit is allowed to cure. In an embodiment, the circuit is allowed to cure at room temperature for at least 4 hours, at least 6 hours, at least 8 hours, at least 10 hours, at least 12 hours, at least 14 hours, at least 16 hours, at least 18 hours, at least 20 hours, at least 22 hours, or at least 24 hours. In another embodiment, the circuit is allowed to cure at an elevated temperature, for instance, between 40° C. to 80° C., for less than 10 hours, less than 8 hours, less than 6 hours, less than 4 hours, less than 2 hours, or less than 1 hour.

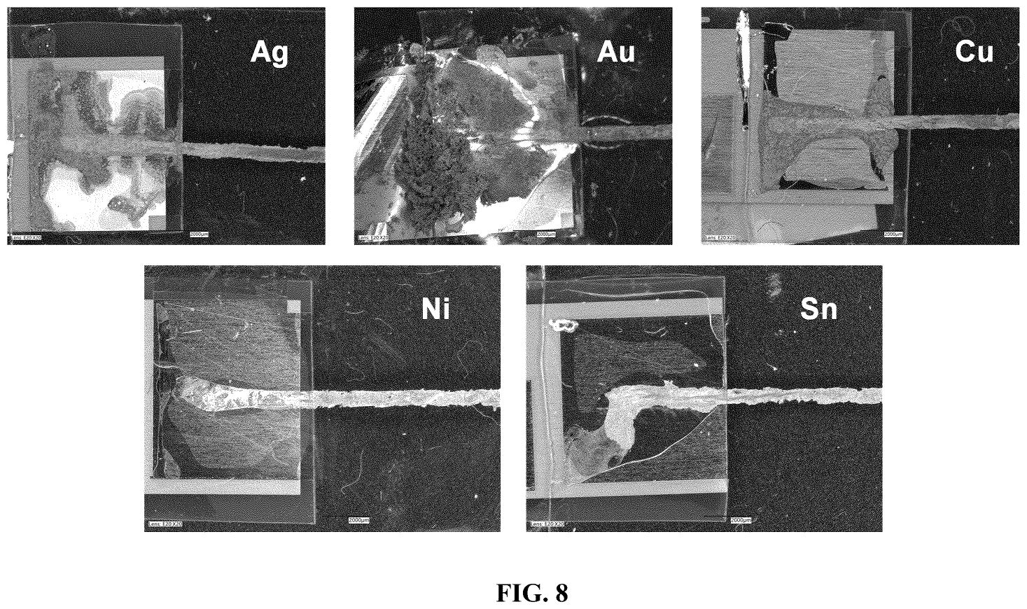

Referring to FIG. 8, there is shown interactions between a liquid metal (EGaIn) and different interconnect materials. The interconnect materials are silver (Ag), gold (Au), copper (Cu), nickel (Ni), and tin (Sn). The images were taken after the testing samples had been placed in a chamber for 500 hours and during 500 hours for 500 thermal cycles from −30° C. to 75° C. This thermal cycling test simulates extremely harsh environmental conditions. As can be seen, Ag, Au, Cu and Sn all react with EGaIn in some degrees and deteriorates the interconnection. Among the tested samples, only Ni shows no visible reaction with EGaIn after 500 hours of thermal cycles. In other words, as an interconnect material to be used with EGaIn, Ni is chemically more stable than Ag, Au, Cu and Sn.

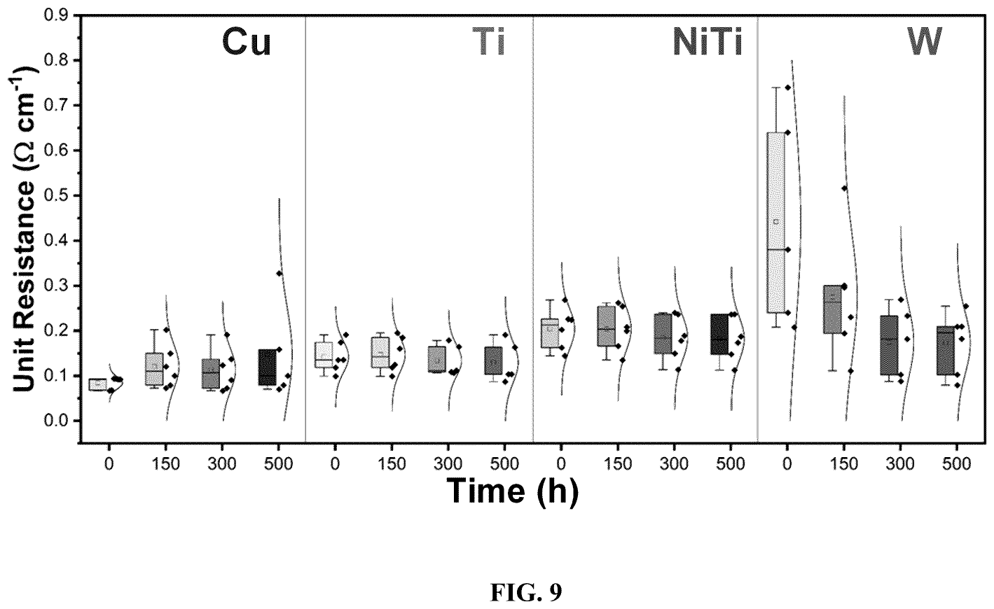

Referring to FIG. 9, there is shown a plot of measured resistances of testing samples with different interconnect materials. The testing samples are the EGaIn/Cu sample (i.e., an EGaIn channel with a copper wire electrical terminal), the EGaIn/Ti sample (i.e., an EGaIn channel with a titanium wire electrical terminal), the EGaIn/NiTi sample (i.e., an EGaIn channel with a nitinol wire electrical terminal), and the EGaIn/W sample (i.e., an EGaIn channel with a tungsten wire electrical terminal). The resistance of the LM-channels were measured using LCR-meter Keysight E4880AL (frequency 1.5 kHz, 1 V). The measurement was conducted at four different time points: before the thermal cycling test, after 150 hours of thermal cycles, after 300 hours of thermal cycles and after 500 hours of thermal cycles. All thermal cycles were from −30° C. to 75° C. The resistance values in the plot are for the samples at 0% strain, i.e., the samples were not stretched at any time during this experiment. As can be seen, there is no significant change of resistance after 500 hours of thermal cycles for all four samples.

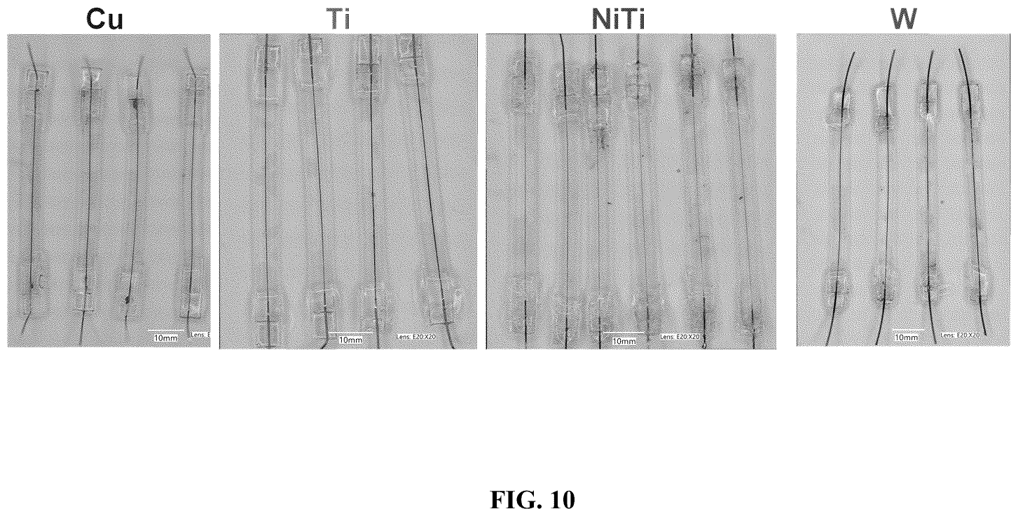

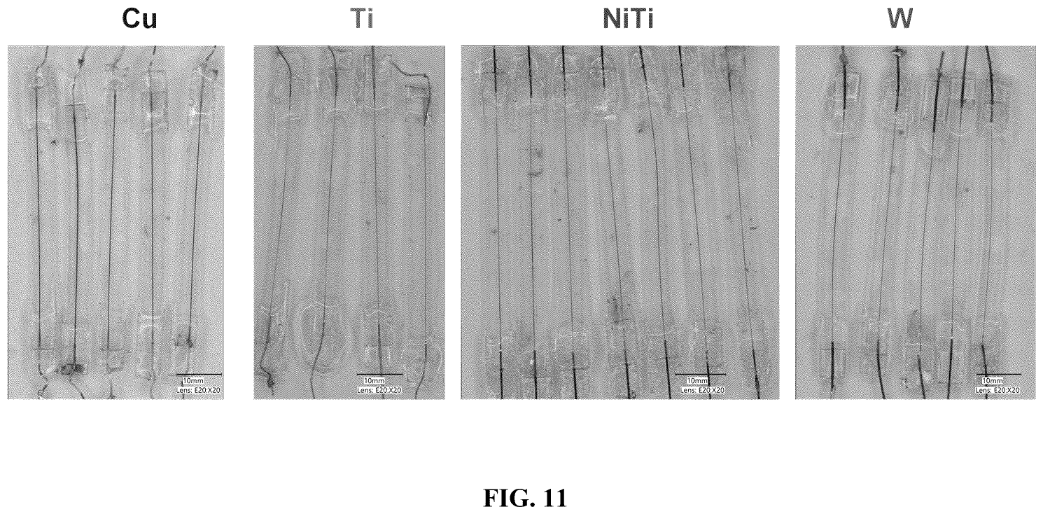

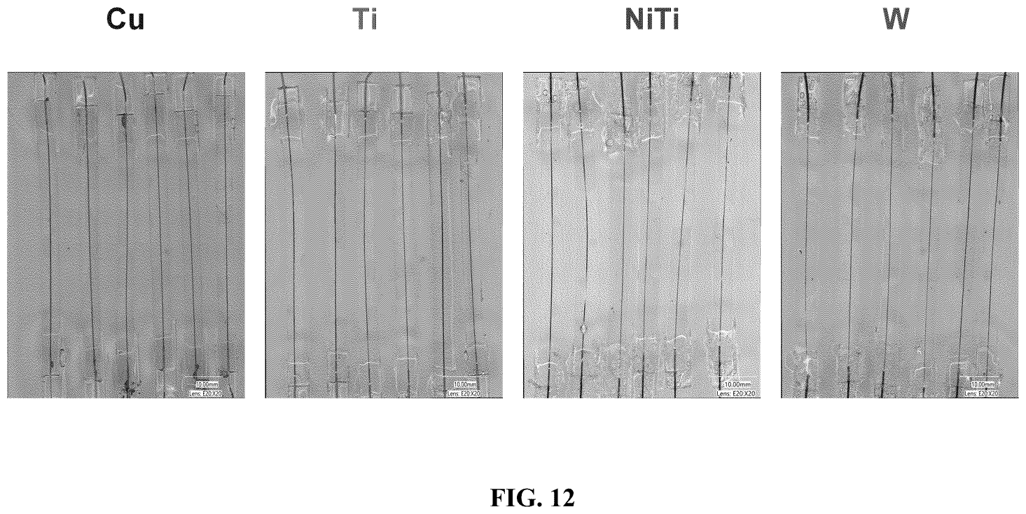

Referring to FIGS. 10-12, there are shown images of testing samples taken at three time points. Images in FIG. 10 were taken after 150 hours of thermal cycles. As can be seen, there is no visible change for all four samples. Images in FIG. 11 were taken after 300 hours of thermal cycles. As can be seen, the color of the EGaIn/Cu sample is getting dark, indicating that EGaIn is reacting with Cu. There is no visible change for the EGaIn/Ti, EGaIn/NiTi, and EGaIn/W samples. Images in FIG. 12 were taken after 500 hours of thermal cycles. As can be seen, the EGaIn oxide is forming through the ends in the EGaIn/Cu sample. There is no visible change for the EGaIn/Ti, EGaIn/NiTi, and EGaIn/W samples. This indicates that Ti, NiTi and W are not reacting with EGaIn during 500 hours of thermal cycles from −30° C. to 75° C.

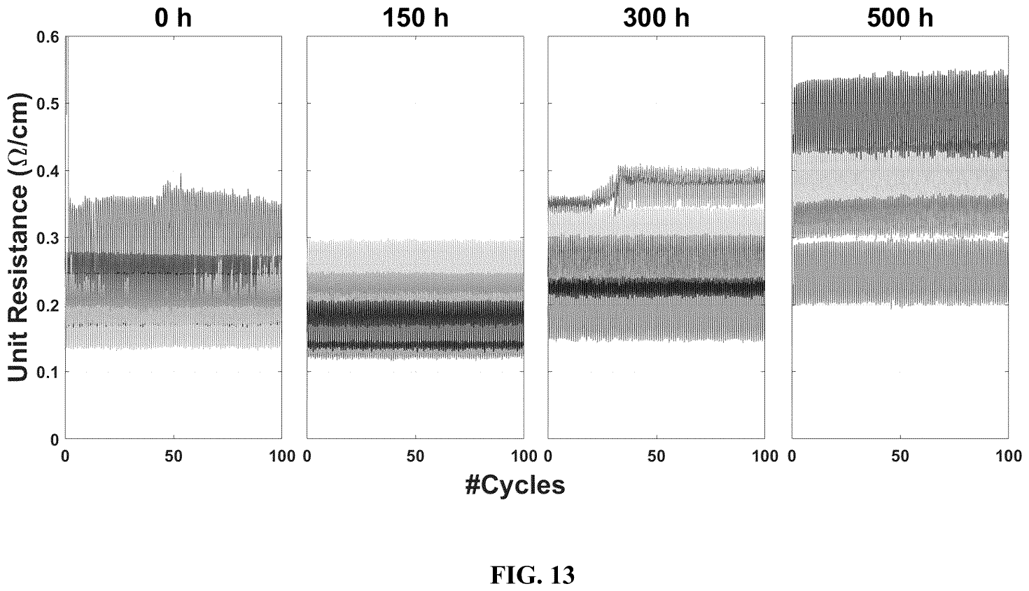

Referring to FIG. 13, there are shown resistance graphs of the EGaIn/Cu sample. The resistances were measured at four different time points: before the thermal cycling test, after 150 hours of thermal cycles, after 300 hours of thermal cycles and after 500 hours of thermal cycles from −30° C. to 75° C.

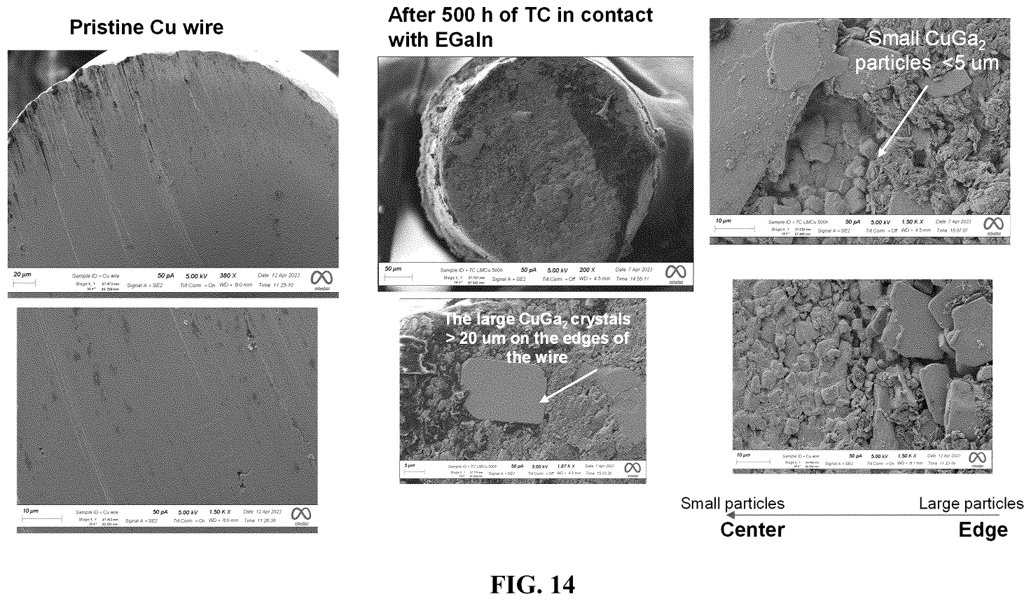

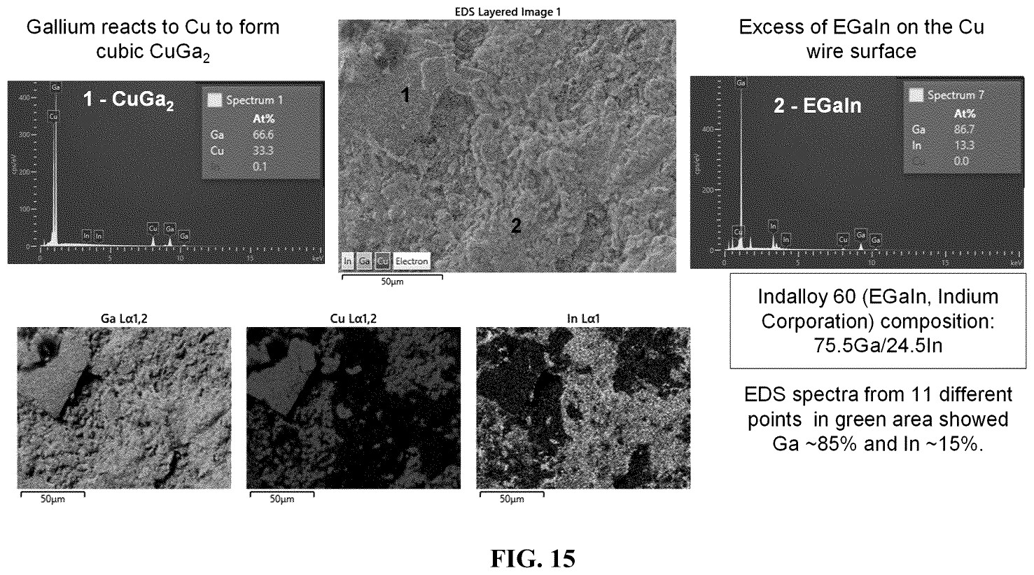

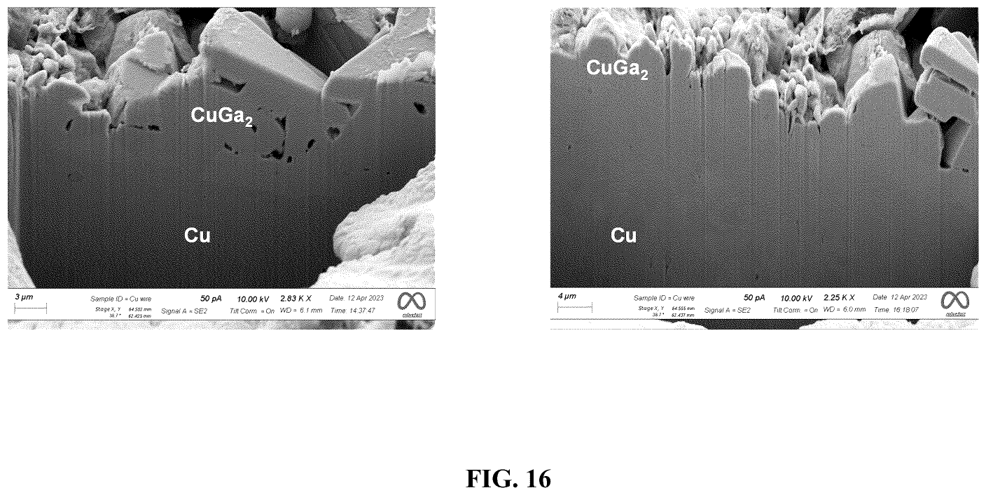

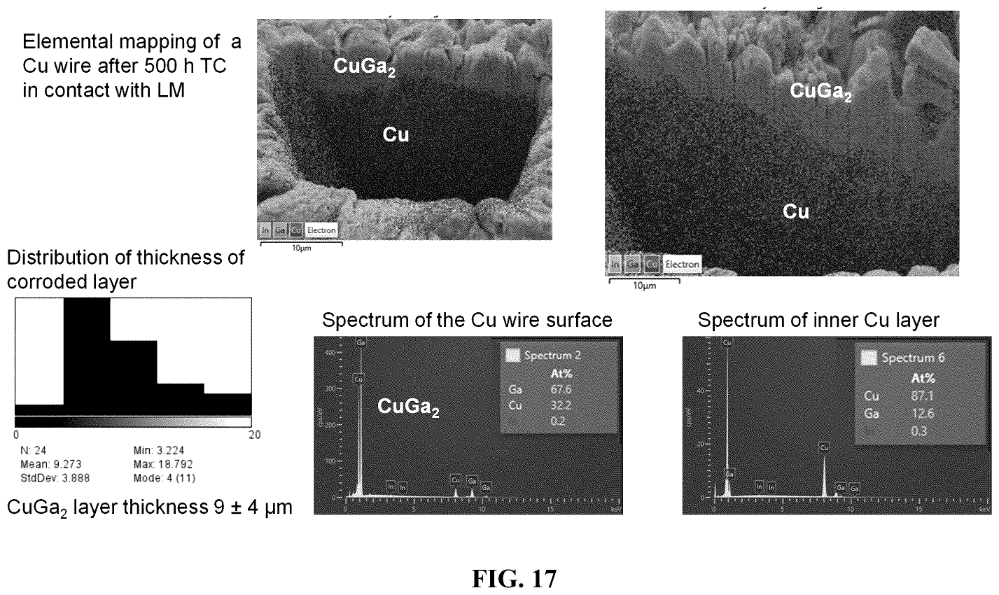

Referring to FIGS. 14-17, there are shown chemical reactivity of EGaIn with copper after 500 hours of thermal cycles. For comparison, FIG. 14 shows a pristine Cu wire in the two images on the left side and the EGaIn/Cu sample after 500 hours of thermal cycles from −30° C. to 75° C. in the remaining four images. As can be seen, after 500 hours of thermal cycles, there are large CuGaz crystals (>20 μm) formed on the edges of the wire. There are also small CuGaz particles (<5 μm) formed toward the center of the Cu wire. FIG. 15 shows images of the EGaIn/Cu sample after 500 hours of thermal cycles and analysis results using an energy dispersive spectroscopy (EDS) that determines the chemical elements and their relative abundance. As can be seen, gallium reacts to Cu to form cubic CuGaz at location 1 on the EDS layered image, and excess of EGaIn is formed at location 2 (the Cu wire surface) on the EDS layered image. FIG. 16 shows the formation of cubic CuGaz. FIG. 17 shows, in the upper two images, elemental mapping of the EGaIn/Cu sample (i.e., the Cu wire after 500 hours of thermal cycles in contact with EGaIn). FIG. 17 also shows, in the lower left plot, the distribution of the thickness of the corroded layer. For the tested EGaIn/Cu sample, it is found that the thickness of CuGaz is 9±4 FIG. 17 further shows, in the lower middle and right plots, a spectrum of the Cu wire surface and a spectrum of the inner Cu layer that confirm the presence of CuGaz.

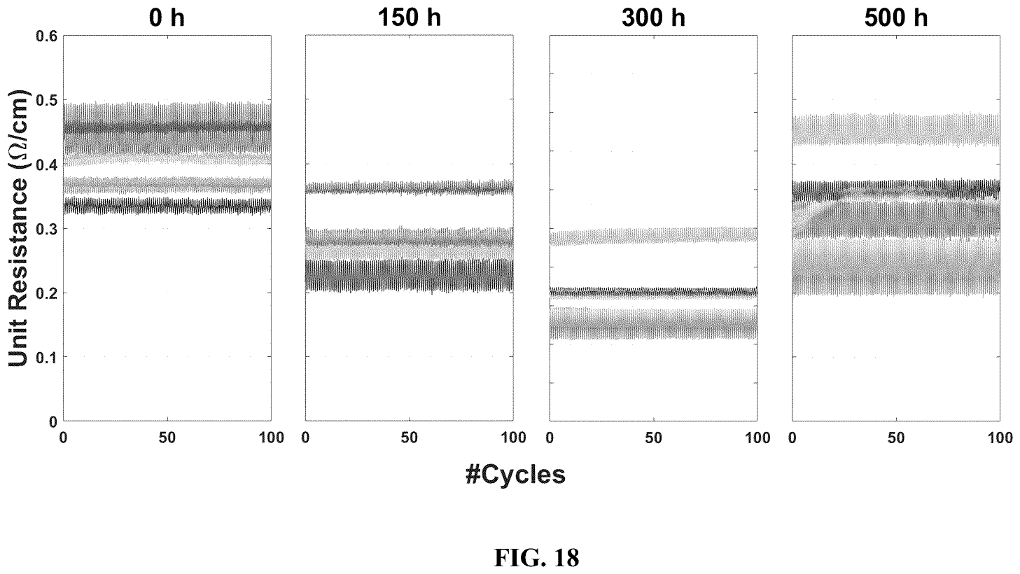

Referring to FIG. 18, there are shown resistance graphs of the EGaIn/NiTi sample. The resistances were measured at four different time points: before the thermal cycling test, after 150 hours of thermal cycles, after 300 hours of thermal cycles and after 500 hours of thermal cycles from −30° C. to 75° C.

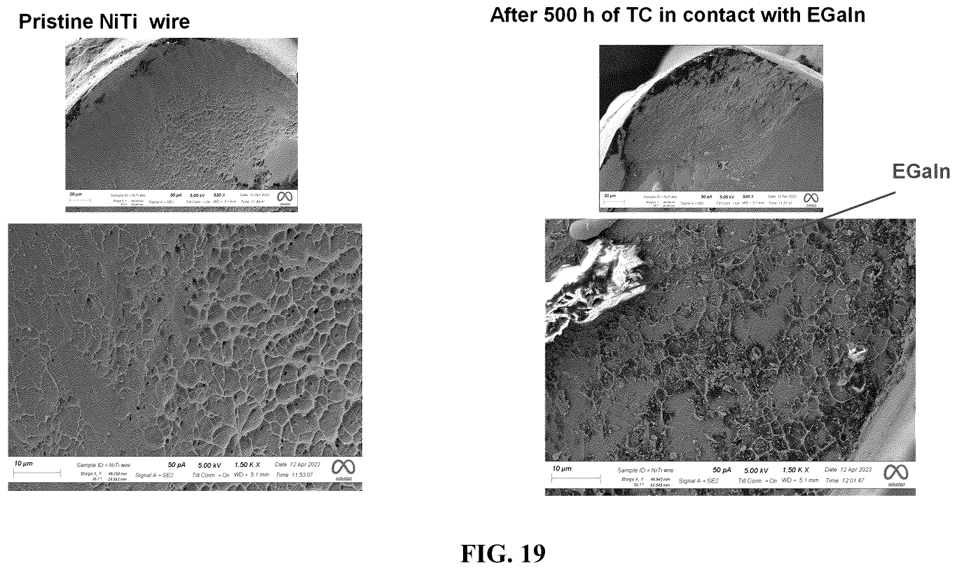

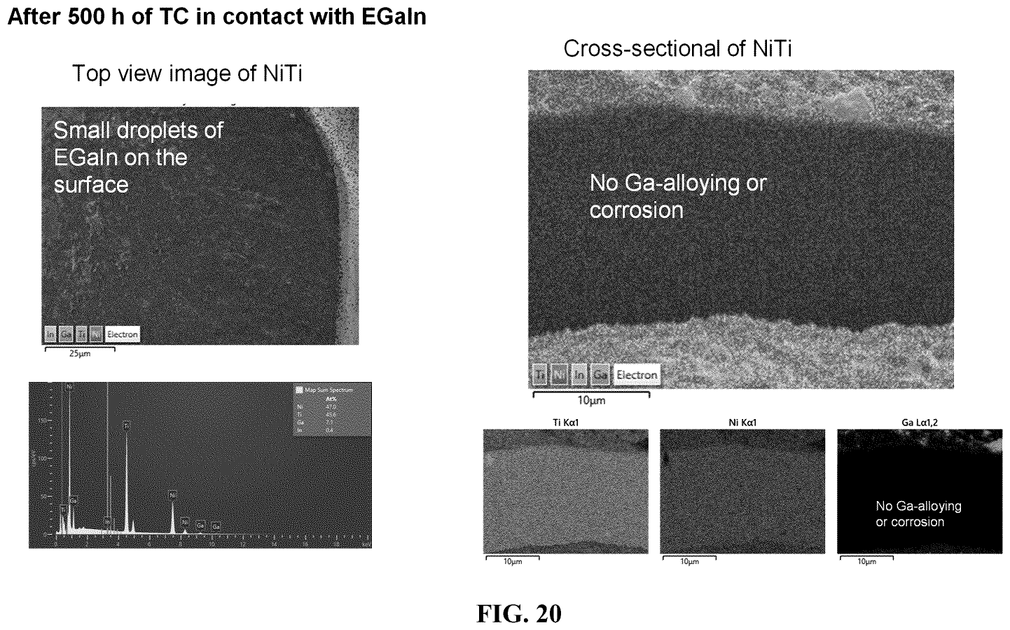

Referring to FIGS. 19 and 20, there are shown chemical reactivity of EGaIn with NiTi (nitinol) after 500 hours of thermal cycles. For comparison, FIG. 19 shows a pristine NiTi wire in the two images on the left side and the EGaIn/NiTi sample after 500 hours of thermal cycles from −30° C. to 75° C. in the two images on the right side. As can be seen, after 500 hours of thermal cycles, there is no visible alloying or corrosion. FIG. 20 shows images of the test sample after 500 hours of thermal cycles and EDS analysis results. Specifically, FIG. 20 shows, on the left side, a top view image of the EGaIn/NiTi sample and a spectrum of the NiTi surface. As can be seen, there are only small droplets of EGaIn on the NiTi surface. FIG. 20 also shows, on the right side, cross-sectional images of the NiTi wire. As can be seen, there is no Ga-alloying or corrosion. This indicates that NiTi is not reacting with EGaIn during 500 hours of thermal cycles from −30° C. to 75° C.

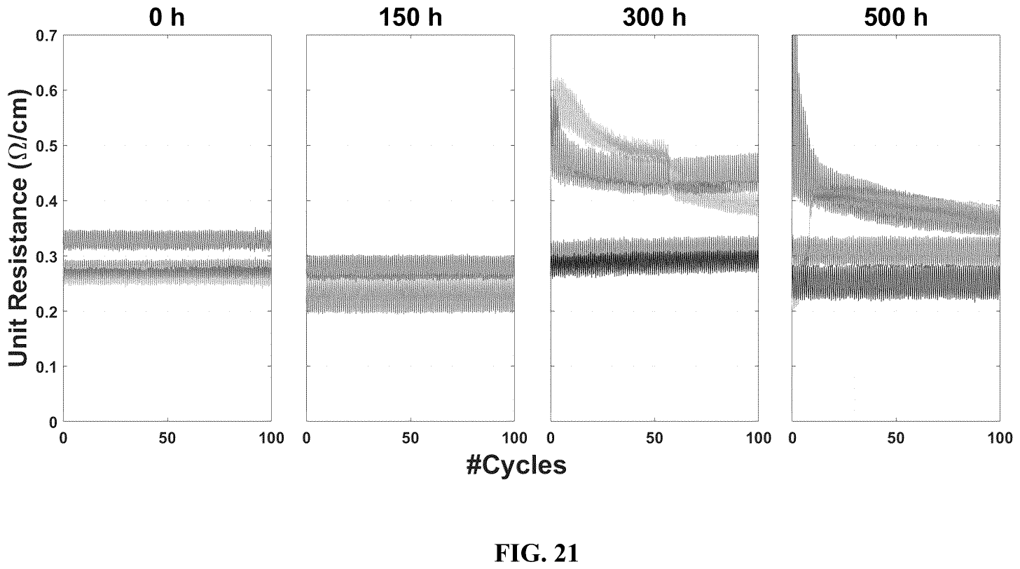

Referring to FIG. 21, there are shown resistance graphs of the EGaIn/Ti sample. The resistances were measured at four different time points: before the thermal cycling test, after 150 hours of thermal cycles, after 300 hours of thermal cycles and after 500 hours of thermal cycles from −30° C. to 75° C.

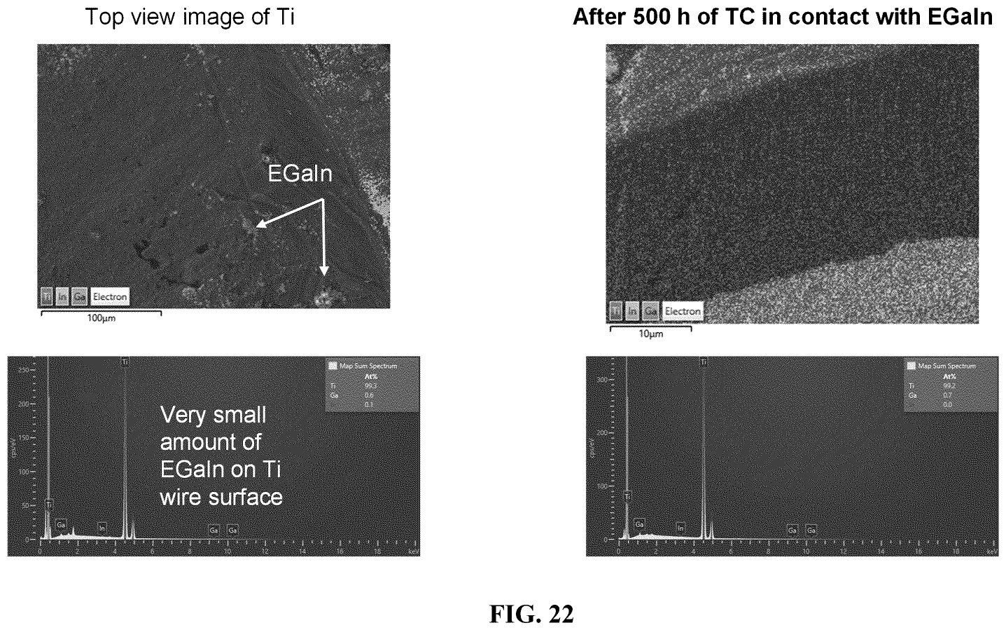

Referring to FIG. 22, there are shown chemical reactivity of EGaIn with Ti after 500 hours of thermal cycles. Specifically, FIG. 22 shows, on the left side, a top view image of the EGaIn/Ti sample and a spectrum of the Ti surface. As can be seen, there are only very small amount of EGaIn on the Ti wire surface. FIG. 22 also shows, on the right side, a cross-sectional image of the Ti wire and a spectrum of the inner Ti layer. As can be seen, there is no Ga-alloying or corrosion. This indicates that Ti is not reacting with EGaIn during 500 hours of thermal cycles from −30° C. to 75° C.

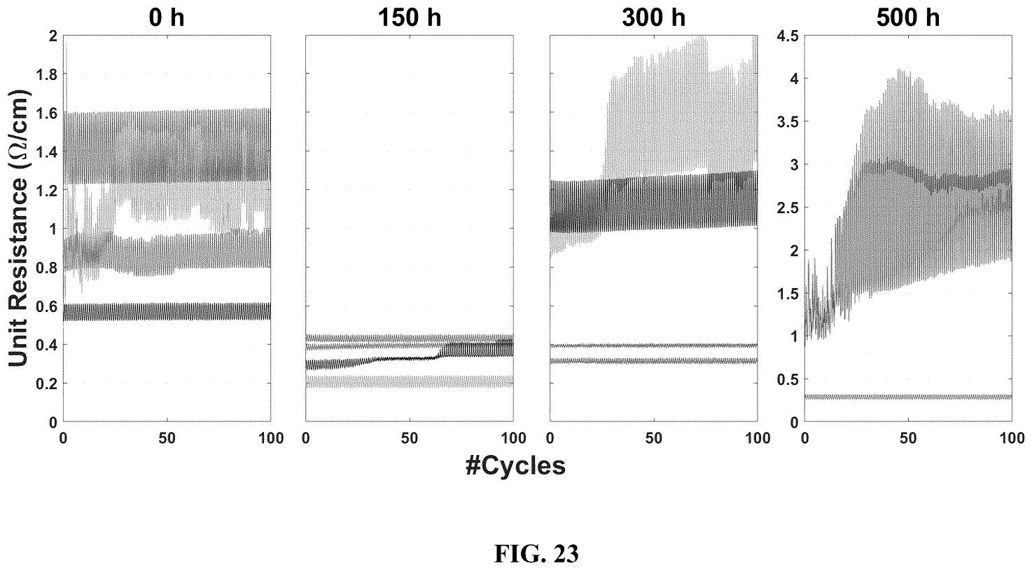

Referring to FIG. 23, there are shown resistance graphs of the EGaIn/W sample. The resistances were measured at four different time points: before the thermal cycling test, after 150 hours of thermal cycles, after 300 hours of thermal cycles and after 500 hours of thermal cycles from −30° C. to 75° C.

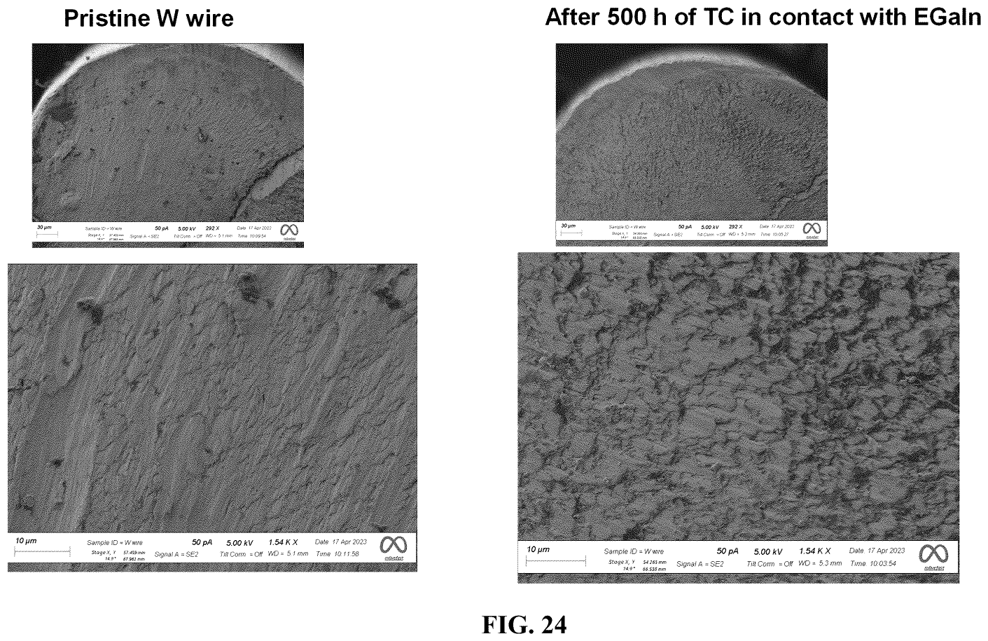

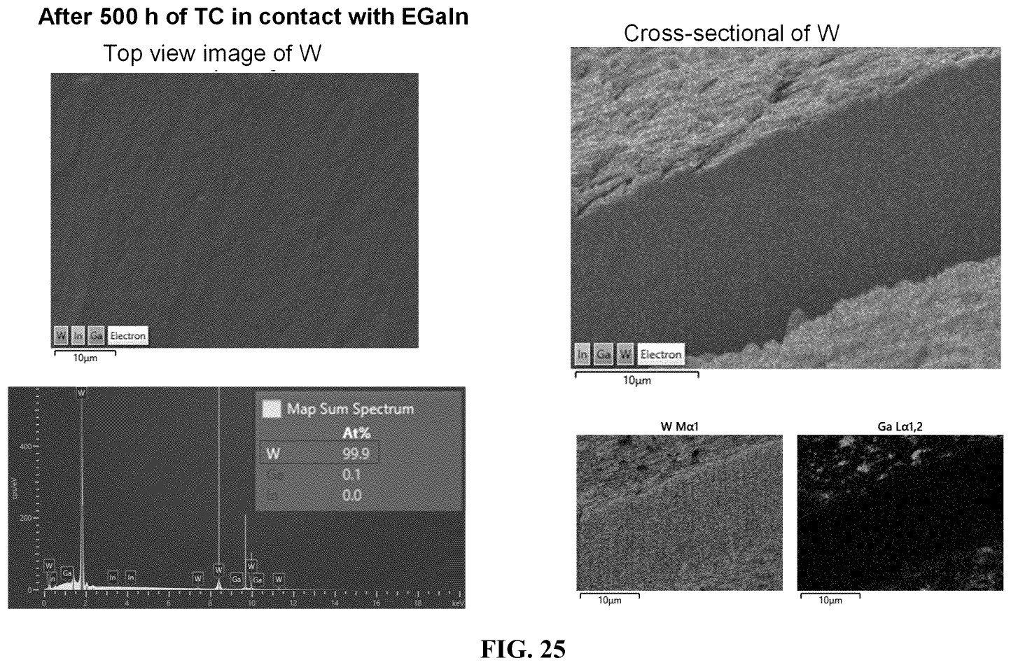

Referring to FIGS. 24 and 25, there are shown chemical reactivity of EGaIn with W (tungsten) after 500 hours of thermal cycles. For comparison, FIG. 24 shows a pristine W wire in the two images on the left side and the EGaIn/W sample after 500 hours of thermal cycles from −30° C. to 75° C. in the two images on the right side. As can be seen, after 500 hours of thermal cycles, there is no visible alloying or corrosion. FIG. 25 shows images of the test sample after 500 hours of thermal cycles and EDS analysis results. Specifically, FIG. 25 shows, on the left side, a top view image of the EGaIn/W sample and a spectrum of the W surface. As can be seen, there is almost no EGaIn on the W wire surface. FIG. 25 also shows, on the right side, cross-sectional images of the W wire. As can be seen, there is no Ga-alloying or corrosion. This indicates that W is not reacting with EGaIn during 500 hours of thermal cycles from −30° C. to 75° C.

In summary, the thermal cycling tests show that NiTi, Ti, and W are not reacting with EGaIn and are chemically stable during 500 hours of thermal cycles from −30° C. to 75° C. As such, NiTi, Ti, and W can be used along with EGaIn to reduce corrosion at liquid metal/metal interfaces and thus improve the integrity and stability of circuits even in very harsh environmental conditions.

### Exemplary Implementations

Implementation 1. An electronic device includes a substrate and a circuit having a plurality of electrically-conductive components disposed on the substrate. The plurality of electrically-conductive components includes first, second and third electrically-conductive components. The first electrically-conductive component is at a first portion of the substrate and is made of a first material including a first metal. The second electrically-conductive component is at a second portion of the substrate and is made of a second material including the first metal. The third electrically-conductive component includes a first end portion and a second end portion. The first end portion forms a first interface with the first electrically-conductive component. The second end portion forms a second interface with the second electrically-conductive component. The third electrically-conductive component is made of a third material including a gallium-based (Ga-based) alloy and a metallic filler, and forms an electrical conduit between the first interface and the second interface. The metallic filler reduces a reactivity of the third electrically-conductive component with the first metal at the first and second interfaces so that each of the first and second interfaces is free of deterioration in conductivity for a period of time, wherein the period of time is at least 1000 hours.

Implementation 2. The electronic device of Implementation 1, wherein the substrate is a deformable substrate.

Implementation 3. The electronic device of Implementation 1 or Implementation 2, wherein the substrate includes one or more layers and wherein the first, second and third electrically-conductive components are in a common layer of the substrate.

Implementation 4. The electronic device of Implementation 1 or Implementation 2, wherein the substrate includes a plurality of layers, wherein the first electrically-conductive component is in a first layer of the substrate, and the second electrically-conductive component is in a second different layer of the substrate.

Implementation 5. The electronic device of any one of Implementations 1-4, wherein the first electrically-conductive component is a first metallic pad or a first electrode, and the second electrically-conductive component is a second metallic pad or a second electrode.

Implementation 6. The electronic device of any one of Implementations 1-3 or 5, wherein the third electrically-conductive component is a single trace or a plurality of traces.

Implementation 7. The electronic device of any one of Implementations 4-5, wherein the third electrically-conductive component is a via between the first layer and the second different layer.

Implementation 8. The electronic device of any one of Implementations 1-7, wherein the first metal is silver, copper, gold, or any combination thereof.

Implementation 9. The electronic device of any one of Implementations 1-8, wherein the Ga-based alloy is a Ga-based liquid metal alloy.

Implementation 10. The electronic device of Implementation 9, wherein the Ga-based liquid metal alloy includes at least one of gallium indium alloy, gallium tin alloy, gallium indium tin alloy, or gallium indium tin zinc alloy.

Implementation 11. The electronic device of any one of Implementations 1-10, wherein the metallic filler is in the form of microflakes, nanoflakes, microparticles, nanoparticles, nanowires, nanotubes, or a combination thereof.

Implementation 12. The electronic device of any one of Implementations 1-11, wherein an amount of the metallic filler in the third material is from about 10% to about 30% by weight, from about 10% to about 40% by weight, or from about 10% to about 50% by weight of the Ga-based alloy.

Implementation 13. The electronic device of any one of Implementations 1-12, wherein the third material further includes a polymeric binder, a solvent, or both.

Implementation 14. The electronic device of any one of Implementations 1-13, wherein the metallic filler includes the first metal.

Implementation 15. The electronic device of Implementation 14, wherein the first metal is silver, the Ga-based alloy is a Ga-based liquid metal alloy, and the metallic filler includes silver in the form of microflakes, nanoflakes, microparticles, nanoparticles, nanowires, nanotubes, or a combination thereof and mixed with the Ga-based liquid metal alloy.

Implementation 16. The electronic device of any one of Implementations 1-13, wherein the metallic filler includes a second metal different than the first metal.

Implementation 17. The electronic device of Implementation 16, wherein the first metal is silver, the Ga-based alloy is a Ga-based liquid metal alloy, and the metallic filler includes copper or gold in the form of microflakes, nanoflakes, microparticles, nanoparticles, nanowires, nanotubes, or a combination thereof and mixed with the Ga-based liquid metal alloy.

Implementation 18. The electronic device of any one of Implementations 1-17, wherein the metallic filler reduces the reactivity of the Ga-based alloy with the first metal that would otherwise cause corrosion, embrittlement, degradation, or open circuit of the first electrically-conductive component at the first interface, and corrosion, embrittlement, degradation, or open circuit of the second electrically-conductive component at second interface.

Implementation 19. A method for fabricating the electronic device of any one of Implementations 1-18.

Implementation 20. A method of fabricating an electronic device, the method including: A) forming a first electrically-conductive component at a first portion of a substrate, wherein the first electrically-conductive component is made of a first material including a first metal; B) forming a second electrically-conductive component at a second portion of the substrate, wherein the second electrically-conductive component is made of a second material including the first metal; and C) connecting the second electrically-conductive component with the first electrically-conductive component by a third electrically-conductive component, wherein the third electrically-conductive component is made of a third material including a Ga-based alloy and a metallic filler, wherein the metallic filler reduces a reactivity of the third electrically-conductive component with the first metal at the first and second interfaces so that each of the first and second interfaces is free of deterioration in conductivity for a period of time, wherein the period of time is at least 1000 hours.

Implementation 21. The method of Implementation 20, wherein the third electrically-conductive component is printed on the substrate between the first and second electrically-conductive components.

Implementation 22. The method of Implementation 20 or Implementation 21, wherein the third electrically-conductive component is a line or via.

Implementation 23. The method of any one of Implementations 20-22, wherein the connecting includes tracing out one or more lines, one or more vias, or any combination of one or more lines and one or more vias, using the third material, to form (i) one or more first interfaces between the first electrically-conductive component and the one or more lines, one or more vias, or any combination of one or more lines and one or more vias, and (ii) one or more second interfaces between the second electrically-conductive component and the one or more lines, one or more vias, or any combination of one or more lines and one or more vias.

Implementation 24. The method of any one of Implementations 20-23, wherein the electronic device is a display.

Implementation 25. The method of any one of Implementations 20-24, wherein the first electrically-conductive component and the second electrically-conductive component form part of an active-matrix array.

Implementation 26. The method of any one of Implementations 20-25, wherein the one or more first and second interfaces are free of deterioration in conductivity when the substrate is bent around a cylinder that has a radius of between 2 centimeters (cm) and 10 cm for a period of time and then released.

Implementation 27. The method of Implementation 26, wherein the period of time is between 10 seconds and five minutes.

Implementation 28. The method of any one of Implementations 20-27, wherein the first electrically-conductive component and the second electrically-conductive component are part of a transistor switch.

### CONCLUSION

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes.

We claim:

1. An electronic device, comprising:
a substrate; and
a circuit comprising a plurality of electrically-conductive components disposed on the substrate, the plurality of electrically-conductive components comprising:
a first electrically-conductive component at a first portion of the substrate, wherein the first electrically-conductive component is made of a first material comprising a first metal;
a second electrically-conductive component at a second portion of the substrate, wherein the second electrically-conductive component is made of a second material comprising the first metal; and
a third electrically-conductive component comprising a first end portion and a second end portion, wherein
the first end portion forms a first interface with the first electrically-conductive component,
the second end portion forms a second interface with the second electrically-conductive component,
the third electrically-conductive component is made of a third material comprising a gallium-based (Ga-based) alloy and a metallic filler,
the third electrically-conductive component forms an electrical conduit between the first interface and the second interface, and
the metallic filler reduces a reactivity of the third electrically-conductive component with the first metal at the first and second interfaces so that each of the first and second interfaces is free of deterioration in conductivity for a period of time, wherein the period of time is at least 1000 hours.

2. The electronic device of claim 1, wherein the substrate is a deformable substrate.

3. The electronic device of claim 1, wherein the substrate comprises one or more layers and wherein the first, second and third electrically-conductive components are in a common layer of the substrate.

4. The electronic device of claim 1, wherein the substrate comprises a plurality of layers, wherein the first electrically-conductive component is in a first layer of the substrate, and the second electrically-conductive component is in a second different layer of the substrate.

5. The electronic device of claim 1, wherein the first electrically-conductive component is a first metallic pad or a first electrode, and the second electrically-conductive component is a second metallic pad or a second electrode.

6. The electronic device of claim 1, wherein the third electrically-conductive component is a single trace or a plurality of traces.

7. The electronic device of claim 4, wherein the third electrically-conductive component is a via between the first layer and the second different layer.

8. The electronic device of claim 1, wherein the first metal is silver, copper, gold, titanium, nitinol, or tungsten, or any combination thereof.

9. The electronic device of claim 1, wherein the Ga-based alloy is a Ga-based liquid metal alloy.

10. The electronic device of claim 9, wherein the Ga-based liquid metal alloy comprises at least one of gallium indium alloy, gallium tin alloy, gallium indium tin alloy, or gallium indium tin zinc alloy.

11. The electronic device of claim 1, wherein the metallic filler is in the form of microflakes, nanoflakes, microparticles, nanoparticles, nanowires, nanotubes, or a combination thereof.

12. The electronic device of claim 1, wherein an amount of the metallic filler in the third material is from about 10% to about 30% by weight, from about 10% to about 40% by weight, or from about 10% to about 50% by weight of the Ga-based alloy.

13. The electronic device of claim 1, wherein the third material further comprises a polymeric binder, a solvent, or both.

14. The electronic device of claim 1, wherein the metallic filler comprises the first metal.

15. The electronic device of claim 14, wherein the first metal is silver, titanium, nitinol, or tungsten, the Ga-based alloy is a Ga-based liquid metal alloy, and the metallic filler comprises silver, titanium, nitinol, or tungsten in the form of microflakes, nanoflakes, microparticles, nanoparticles, nanowires, nanotubes, or a combination thereof and mixed with the Ga-based liquid metal alloy.

16. The electronic device of claim 1, wherein the metallic filler comprises a second metal different than the first metal.

17. The electronic device of claim 1, wherein the metallic filler reduces the reactivity of the Ga-based alloy with the first metal that would otherwise cause corrosion, embrittlement, degradation, or open circuit of the first electrically-conductive component at the first interface, and corrosion, embrittlement, degradation, or open circuit of the second electrically-conductive component at second interface.

18. A method of fabricating an electronic device, the method comprising:
forming a first electrically-conductive component at a first portion of a substrate, wherein the first electrically-conductive component is made of a first material comprising a first metal;
forming a second electrically-conductive component at a second portion of the substrate, wherein the second electrically-conductive component is made of a second material comprising the first metal; and
connecting the second electrically-conductive component with the first electrically-conductive component by a third electrically-conductive component, wherein the third electrically-conductive component is made of a third material comprising a Ga-based alloy and a metallic filler,
wherein the metallic filler reduces a reactivity of the third electrically-conductive component with the first metal at the first and second interfaces so that each of the first and second interfaces is free of deterioration in conductivity for a period of time, wherein the period of time is at least 1000 hours.

19. The method of claim 18, wherein the third electrically-conductive component is a line or via.

20. The method of claim 18, wherein the connecting comprises tracing out one or more lines, one or more vias, or any combination of one or more lines and one or more vias, using the third material, to form (i) one or more first interfaces between the first electrically-conductive component and the one or more lines, one or more vias, or any combination of one or more lines and one or more vias, and (ii) one or more second interfaces between the second electrically-conductive component and the one or more lines, one or more vias, or any combination of one or more lines and one or more vias.
